(19) United States
(12) Patent Application Publication
(10) Pub. No.: US 2025/0105150 A1
(43) Pub. Date: Mar. 27, 2025

(54) SEMICONDUCTOR DEVICES

(71) Applicant: Samsung Electronics Co., Ltd., Suwon-si (KR)

(72) Inventors: Jeon Il Lee, Suwon-si (KR); Seryeun Yang, Suwon-si (KR); Dongkyun Lim, Suwon-si (KR)

(21) Appl. No.: 18/625,407

(22) Filed: Apr. 3, 2024

(30) Foreign Application Priority Data
Sep. 25, 2023 (KR) 10-2023-0128557

(51) Int. Cl. H01L 23/528; H01L 23/522; H01L 25/065; H10B 12/00; H10B 80/00

(52) U.S. Cl. CPC H01L 23/5283; H01L 23/5226; H01L 25/0657; H10B 12/315; H10B 80/00; H01L 2225/06541

(57) ABSTRACT

A semiconductor device may include a substrate that includes a first surface and a second surface opposite to each other, a first driving transistor and a second driving transistor on the first surface of the substrate, a first insulation layer on the first surface of the substrate, a second insulation layer on the second surface of the substrate, a first penetration electrode and a second penetration electrode that extend into the substrate, the first insulation layer, and the second insulation layer, a first contact plug extending in the first insulation layer and electrically connected to the first driving transistor and the first penetration electrode, and a second contact plug extending in the substrate and the second insulation layer and electrically connected to the second driving transistor and the second penetration electrode.

### CROSS-REFERENCE TO RELATED APPLICATION

This application claims priority to and the benefit of Korean Patent Application No. 10-2023-0128557 filed in the Korean Intellectual Property Office on Sep. 25, 2023, the entire contents of which is incorporated herein by reference.

### BACKGROUND OF THE INVENTION

The present disclosure relates to semiconductor devices.

A semiconductor is a material that falls between a conductor and an insulator, and refers to a material that conducts electricity under certain conditions. Various semiconductor devices, for example, memory devices and the like, may be manufactured using semiconductor materials. These semiconductor elements may be used in various electronic devices.

Meanwhile, in the semiconductor industry, demand for high capacity, thinness, and miniaturization of semiconductor devices and electronic products using the same is increasing.

In accordance with the trend of miniaturization and high integration of electronic devices, there is a need to accurately and quickly apply a signal to a semiconductor element while reducing an area occupied by a peripheral portion for applying a predetermined signal to the semiconductor element.

### SUMMARY OF THE INVENTION

The present disclosure aims to provide a semiconductor device capable of accurately and quickly applying a signal to a semiconductor element while reducing an area occupied by a peripheral portion for applying a predetermined signal to the semiconductor element.

However, the problems to be solved by embodiments of the present disclosure are not limited to the above, and other problems to be solved will be more clearly understood from the following description.

According to some embodiments, a semiconductor device may include a substrate that includes a first surface and a second surface opposite to each other, a first driving transistor and a second driving transistor on the first surface of the substrate, a first insulation layer on the first surface of the substrate, a second insulation layer on the second surface of the substrate, a first penetration electrode and a second penetration electrode that extend into the substrate, the first insulation layer, and the second insulation layer, a first contact plug extending in the first insulation layer and electrically connected to the first driving transistor and the first penetration electrode, and a second contact plug extending in the substrate and the second insulation layer and electrically connected to the second driving transistor and the second penetration electrode.

According to some embodiments, a semiconductor device may include a die, a plurality of semiconductor chips electrically connected to the die and stacked along a first direction, and a molding material that at least partially surrounds the plurality of semiconductor chips. At least one of the plurality of semiconductor chips may include a substrate including a cell array region, a core region, and a connection region, the substrate having a first surface and a second surface opposite to each other, a first driving transistor and a second driving transistor on the first surface of the substrate and in the core region, a first insulation layer on the first surface of the substrate, a second insulation layer on the second surface of the substrate, a first penetration electrode and a second penetration electrode that are in the connection region and extend into the substrate, the first insulation layer, and the second insulation layer, a first contact plug extending in the first insulation layer and electrically connected to the first driving transistor and the first penetration electrode, and a second contact plug extending in the substrate and the second insulation layer and electrically connected to the second driving transistor and the second penetration electrode.

According to some embodiments, a semiconductor device may include a substrate that includes a first surface and a second surface opposite to each other, a first driving transistor and a second driving transistor on the first surface of the substrate, a first insulation layer on the first surface of the substrate, a second insulation layer on the second surface of the substrate, a first contact plug extending in the first insulation layer and electrically connected to the first driving transistor, and a second contact plug extending in the substrate and the second insulation layer and electrically connected to the second driving transistor. The first driving transistor may be configured to receive a first signal through the first contact plug, and the second driving transistor may be configured to receive a second signal through the second contact plug. One of the first and second signals may be a data signal, and another one of the first and second signals may be a power signal.

According to example embodiments, a semiconductor device capable of accurately and quickly applying a signal to a semiconductor element while reducing an area occupied by a peripheral portion for applying a predetermined signal to the semiconductor element may be provided.

Example embodiments of the present disclosure are not limited to the above-described effect, and may be variously modified without departing from the scope of this disclosure.

### BRIEF DESCRIPTION OF THE DRAWINGS

FIG. 1 is a schematic drawing showing a semiconductor device according to some embodiments.

FIG. 2 is a top plan view showing a portion of FIG. 1.

FIG. 3 is an enlarged top plan view of a partial region of FIG. 2.

FIG. 4 is a cross-sectional view of FIG. 3.

FIG. 5 is a cross-sectional view taken along line I-I′ of FIG. 2.

FIG. 6 is a cross-sectional view taken along line II-II′ of FIG. 2.

FIGS. 7 to 16 are cross-sectional views showing a manufacturing method of a semiconductor device according to some embodiments.

FIG. 17 is a cross-sectional view of a semiconductor device taken along line I-I′ of FIG. 2 according to some embodiments.

FIG. 18 is a cross-sectional view of a semiconductor device taken along line II-II′ of FIG. 2 according to some embodiments.

FIG. 19 is a cross-sectional view of a semiconductor device taken along line I-I′ of FIG. 2 according to some embodiments.

FIG. 20 is a cross-sectional view of a semiconductor device taken along line II-II′ of FIG. 2 according to some embodiments.

FIG. 21 is a cross-sectional view of a semiconductor device taken along line I-I′ of FIG. 2 according to some embodiments.

FIG. 22 is a cross-sectional view of a semiconductor device taken along line II-II′ of FIG. 2 according to some embodiments.

FIG. 23 is a schematic drawing showing a semiconductor device according to some embodiments.

FIG. 24 is a schematic drawing showing a semiconductor device according to some embodiments.

FIG. 25 is a schematic drawing showing a semiconductor device according to some embodiments.

### DETAILED DESCRIPTION

Example embodiments of the present disclosure will be described more fully hereinafter with reference to the accompanying drawings, in which example embodiments are shown. As those skilled in the art will appreciate, the described embodiments may be modified in various different ways, all without departing from the scope of this disclosure.

In order to clearly describe the embodiments, parts or portions that are irrelevant to the description may be omitted, and identical or similar constituent elements throughout the specification are denoted by the same reference numerals.

Further, the accompanying drawings are provided to allow embodiments disclosed in the present specification to be more easily understood and are not to be interpreted as limiting the scope of the present disclosure. It is to be understood that the embodiments include all modifications, equivalents, and substitutions without departing from the scope of this disclosure.

Further, in the drawings, the size and thickness of each element may not necessarily be to scale for ease of illustration, and the present disclosure is not necessarily limited to those illustrated in the drawings. In the drawings, the thicknesses of layers, films, panels, regions, areas, etc., may be exaggerated for clarity.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, it will be understood that the terms “on” or “above” can mean positioned above the object portion or below the object portion, and does not necessarily mean positioned on the upper side of the object portion based on a gravitational direction, unless the context clearly indicates so.

In addition, unless explicitly described to the contrary, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

Further, throughout the specification, the phrase “in a plan view” or “on a plane” means viewing a target portion from the top, and the phrase “in a cross-sectional view” or “on a cross-section” means viewing a cross-section formed by vertically cutting a target portion.

Furthermore, throughout the specification, “connected” does not only mean when two or more elements are directly connected, but also when two or more elements are indirectly connected through other elements, and when they are physically connected or electrically connected, and further, it may be referred to by different names depending on a position or function, and may also be referred to as a case in which respective parts that are substantially integrated are linked to each other. In addition, it will be understood that, although the terms first, second, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

Hereinafter, example embodiments will be described in detail with reference to the drawings.

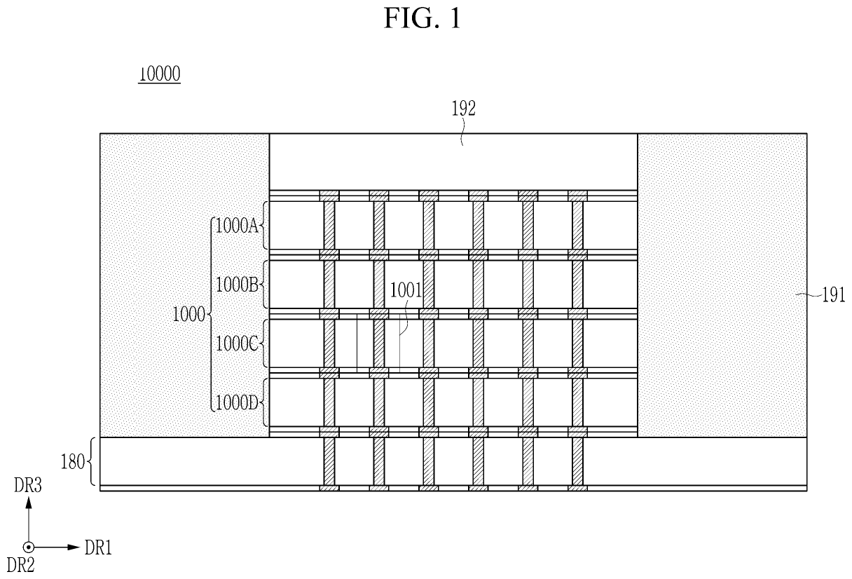

With reference to FIG. 1, a semiconductor device according to some embodiments will be described. FIG. 1 is a schematic drawing showing a semiconductor device according to some embodiments.

Referring to FIG. 1, a semiconductor device 10000 may include a semiconductor chip stacking structure 1000, a bottom die 180, a molding material 191 and a dummy silicon layer 192.

The semiconductor chip stacking structure 1000 may be disposed on the bottom die 180. In some embodiments, the bottom die 180 may have a larger width in a first direction DR1 compared to the semiconductor chip stacking structure 1000.

The semiconductor chip stacking structure 1000 may have a structure in which a plurality of semiconductor chips 1000A, 1000B, 1000C, and 1000D are stacked in one direction, for example, a third direction DR3, which is a height direction perpendicular to the first direction DR1.

In some embodiments, the semiconductor device 10000 may include a high bandwidth memory (HBM). Each of the plurality of semiconductor chips 1000A, 1000B, 1000C, and 1000D stacked in the semiconductor chip stacking structure 1000 may be a memory chip (e.g., DRAM), and the bottom die 180 may be a buffer die. However, embodiments of the present disclosure are not limited thereto.

The semiconductor chip stacking structure 1000 and the bottom die 180 may be bonded by hybrid bonding. Each of the semiconductor chips 1000A, 1000B, 1000C, and 1000D included in the semiconductor chip stacking structure 1000 may be coupled to each other by hybrid bonding. The hybrid bonding may be performed by bonding a junction included in each of the semiconductor chips 1000A, 1000B, 1000C, and 1000D, or the bottom die 180. The junction may be a portion where the plurality of semiconductor chips 1000A, 1000B, 1000C, and 1000D contact each other, and may be a portion where the bottom die 180 and a first one among the plurality of semiconductor chips 1000A, 1000B, 1000C, and 1000D contact each other.

The hybrid bonding is a method for bonding two devices by fusing the same materials of the two devices by using the bonding nature of same materials. For example, this may mean that, in the junction, two devices are bonded to each other by metal-metal bonding and non-metal-non-metal bonding. According to hybrid bonding, I/O with a fine pitch may be formed. Specifically, when two semiconductor chips are bonded to each other, the junction of each semiconductor chip may include one or more metal pads and an insulating layer adjacent to the metal pad. At this time, at the joint, metal pads may be bonded to each other, and insulating layers may be bonded to each other.

The molding material 191 may be disposed above the bottom die 180 along the third direction DR3 to surround the semiconductor chip stacking structure 1000, and the semiconductor chip stacking structure 1000 may be molded by the molding material 191, to be protected and insulated by the molding material 191. It will be understood that “an element A surrounds an element B” (or similar language) as used herein means that the element A is at least partially around the element B but does not necessarily mean that the element A completely encloses the element B. In some embodiments, the molding material 191 may include a thermosetting resin such as an epoxy resin. In some embodiments, the molding material 191 may be an epoxy molding compound EMC. In some embodiments, the process of molding by the molding material 191 may include a compression molding or transfer molding process.

The dummy silicon layer 192 may be disposed above the semiconductor chip stacking structure 1000 along the third direction DR3, and the heat generated within the high bandwidth memory may be dissipated to the outside through the dummy silicon layer 192. The dummy silicon layer 192 may include crystalline silicon. The thermal conductivity of silicon may have a larger value than the thermal conductivity of the molding material 191.

The heat generated at the high bandwidth memory may be effectively dissipated by the dummy silicon layer 192 including silicon.

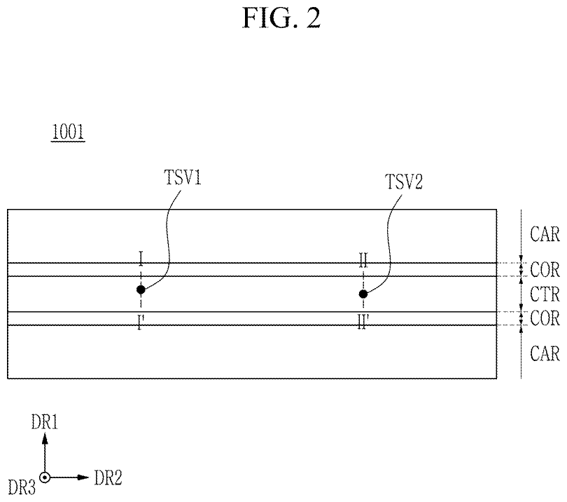

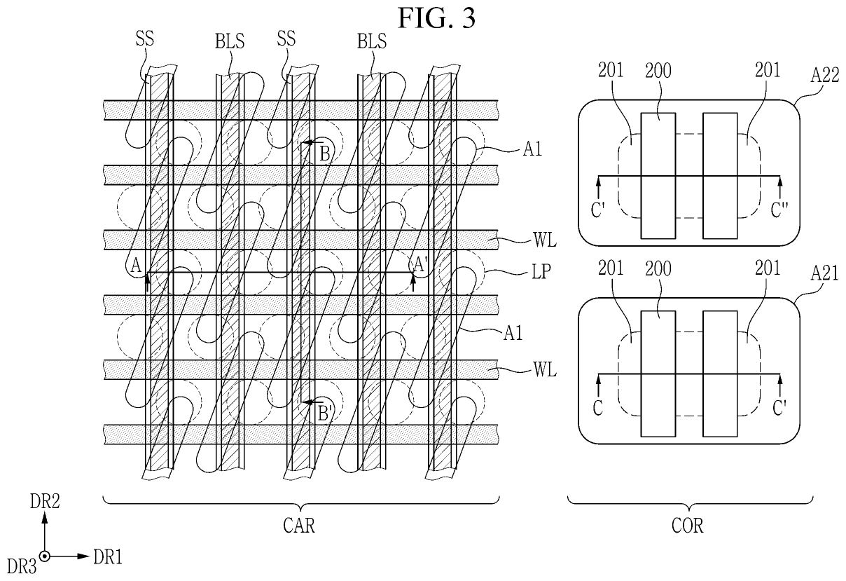

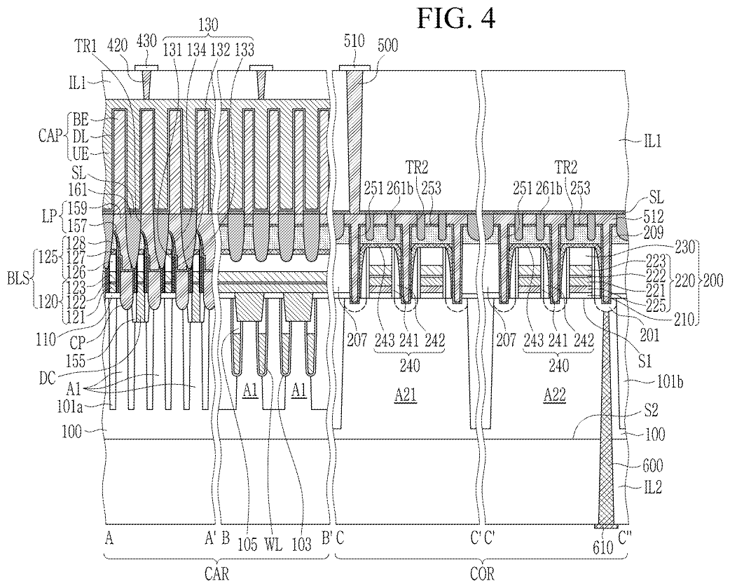

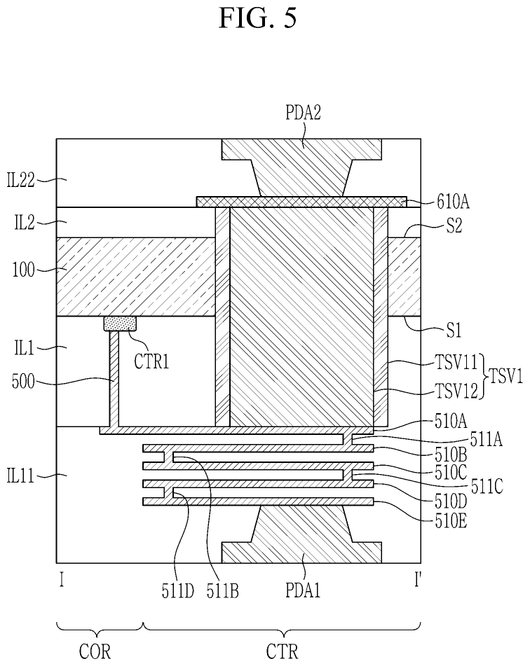

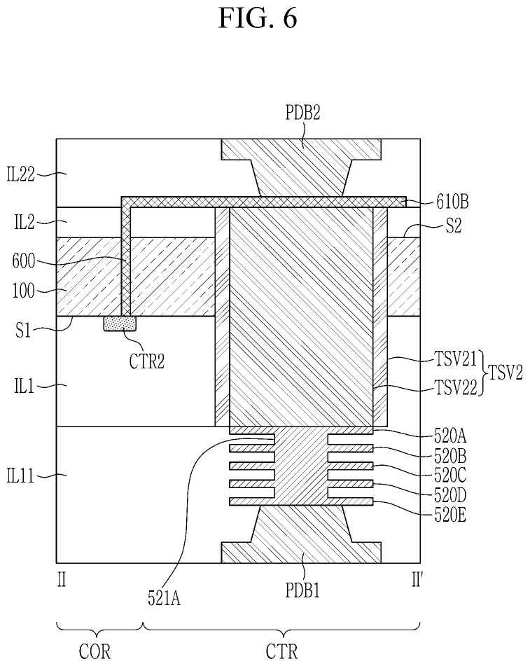

Next, with reference to FIGS. 2 to 6 together with FIG. 1, the plurality of semiconductor chips 1000A, 1000B, 1000C, and 1000D of the semiconductor device 10000 according to some embodiments will be described. FIG. 2 is a top plan view showing a portion of FIG. 1. FIG. 3 is an enlarged top plan view of a partial region of FIG. 2. FIG. 4 is a cross-sectional view of FIG. 3. In particular, FIG. 4 is a cross-sectional view taken along lines A-A′, B-B′, C-C′, and C′-C″ of FIG. 3. FIG. 5 is a cross-sectional view taken along line I-I′ of FIG. 2. FIG. 6 is a cross-sectional view taken along line II-II′ of FIG. 2.

Each of the plurality of semiconductor chips 1000A, 1000B, 1000C, and 1000D of the semiconductor device 10000 may include a plurality of semiconductor elements 1001 (see FIG. 1). Hereinafter, a portion of one semiconductor element 1001 among the plurality of semiconductor elements 1001 included in each of the plurality of semiconductor chips 1000A, 1000B, 1000C, and 1000D of the semiconductor device 10000 is shown.

Referring to FIG. 2, the semiconductor element 1001 may include a cell array region CAR, a core region COR, and a connection region CTR.

The semiconductor element 1001 may have a rectangular shape, in a plan view, including two sides parallel in the first direction DR1 and two sides parallel in a second direction DR2, but is not limited thereto. The second direction DR2 may cross (i.e., intersect) the first direction DR1. The second direction DR2 may perpendicularly cross the first direction DR1.

The connection region CTR may extend longitudinally along the second direction DR2 in a plan view, but is not limited thereto. As used herein, the term “longitudinally” indicates a longest dimension.

The cell array region CAR and the core region COR may be disposed on both sides of the connection region CTR along the first direction DR1.

A plurality of cell array regions CAR may be spaced apart from each other, and the core region COR and the connection region CTR may be disposed between the plurality of cell array regions CAR, but are not limited thereto.

The plurality of cell array regions CAR each may include a memory cell. Each cell array region CAR may include at least one of a memory cell of a volatile memory element or a memory cell of a non-volatile memory device. For example, cell transistors such as a dynamic random access memory (DRAM), a flash memory, and the like may be disposed in the cell array region CAR. The cell array region CAR may include a plurality of unit memory cells for storing information. One unit memory cell may include at least one transistor and at least one capacitor.

A driving circuit configured to generate signals to drive a memory cell disposed in the cell array region CAR and wirings to transfer such signals may be disposed in the core region COR. For example, a sense amplifier, a write driver, etc., and a row decoder, a column decoder, etc. may be disposed in the core region COR.

Wirings for connecting the memory cell and the driving circuit and a contact plug, etc. for connecting them may be disposed in the core region COR.

In the connection region CTR, a plurality of penetration portions TSV1 and TSV2 penetrating (i.e., extending into) the plurality of semiconductor chips 1000A, 1000B, 1000C, and 1000D along the third direction DR3 that is the height direction and connected to each other through junctions and junctions connected to the plurality of penetration portions TSV1 and TSV2 may be disposed.

The cell array region CAR, the core region COR, and the connection region CTR will be described in more detail with reference to FIGS. 3 to 6.

Referring to FIG. 3 and FIG. 4, the semiconductor element 1001 of the semiconductor device according to some embodiments includes a substrate 100 that includes the cell array region CAR and the core region COR.

A first isolation layer 101a that defines first active regions A1 on the cell array region CAR of the substrate 100 may be disposed. The substrate 100 may include silicon, germanium, or silicon-germanium.

The first active regions A1 may be provided on a first surface S1 of the substrate 100. The first active regions A1 may be formed by patterning an upper portion of the substrate 100. The first active regions A1 may have a rectangular (or bar-shaped) shape. The first active regions A1 may be 2-dimensionally arranged along the first direction DR1 and the second direction DR2. The first active regions A1 may have a major axis in an oblique direction with respect to the first direction DR1 and the second direction DR2. Each of the first active regions A1 may have its width decreasing away from a bottom surface of the substrate 100, in a cross-section. That is, each of the first active regions A1 may have a narrowing width in a third direction DR3 perpendicular to an upper surface of the substrate 100.

Word lines WL may be disposed within the substrate 100. In a plan view, the word lines WL may extend in the first direction DR1 and cross the first active regions A1 and the first isolation layer 101a. The word lines WL may be arranged along the second direction DR2. A gate insulation layer 103 may be interposed between the word lines WL and the substrate 100.

In more detail, gate recess regions may be formed within the first active regions A1 and the first isolation layer 101a. The gate insulation layer 103 may conformally be on (e.g., may cover) inner sidewalls of the gate recess regions. The word lines WL may be in (e.g., may fill) lower portions of the gate recess regions. The word lines WL may be spaced apart from the first active regions A1 and the first isolation layer 101a interposing the gate insulation layer 103. Upper surfaces of the word lines WL may be disposed lower than the upper surface of the substrate 100. A gate capping layer 105 may be disposed on the upper surfaces of the word lines WL, so as to be in (e.g., to fill) remaining portions of the gate recess regions. The level of an upper surface of the gate capping layer 105 may be substantially the same as the level of the upper surface of the substrate 100. As used herein, the term “level” indicates a height in a vertical direction (e.g., the third direction DR3) from a lower surface of the substrate 100.

Bit line structures BLS may extend in the second direction DR2 across the first active regions A1 in a plane. The bit line structures BLS may cross but be insulated from the word lines WL. The bit line structures BLS may include a bit line 120 and a bit line capping pattern 125 on the bit line 120.

The bit line 120 may include a polysilicon pattern 121, a silicide pattern 122, and a metal pattern 123 that are sequentially stacked. A lower insulation layer 110 may be interposed between the polysilicon pattern 121 and the substrate 100. A bit line contact pattern DC may be disposed between the bit line 120 and the first active region A1. The bit line 120 may be electrically connected to the first active region A1 through the bit line contact pattern DC. A bottom surface of the bit line contact pattern DC may be disposed lower than the upper surface of the substrate 100, and may be disposed higher than the upper surfaces of the word lines WL. The bit line contact pattern DC may be locally disposed within a recess region formed within the substrate 100 to expose an upper surface the first active region A1. In a plan view, the recess region may have an elliptical shape, and a width of the recess region in a minor axis direction may be larger than a width of the bit line structures BLS.

The bit line capping pattern 125 may be disposed on the metal pattern 123 of the bit line 120. The bit line capping pattern 125 may include a first capping pattern 126, a second capping pattern 127, and a third capping pattern 128 that are sequentially stacked.

A bit line contact spacer 155 may be in (e.g., may fill) a remaining portion of the recess region formed with the bit line contact pattern DC. For example, the bit line contact spacer 155 may be on (e.g., may cover) both sidewalls of the bit line contact pattern DC. As another example, the bit line contact spacer 155 may surround side surfaces of the bit line contact pattern DC within the recess region. The bit line contact spacer 155 may be formed of an insulating material having etching selectivity with respect to the lower insulation layer 110. For example, the bit line contact spacer 155 may include a silicon oxide layer, silicon nitride layer, and/or silicon oxynitride layer, and may be formed as a multilayer spacer. According to some embodiments, an upper surface of the bit line contact spacer 155 may be disposed at a substantially same level as an upper surface of the lower insulation layer 110.

Lower contacts CP may be disposed between sidewalls of the bit line structures BLS. The lower contacts CP may be arranged along the first direction DR1 on sidewalls of the bit line structures BLS. In a plan view, each of the lower contacts CP may be disposed between ones of the word lines WL and between ones of the bit line structures BLS. Each of the lower contacts CP may be connected to the substrate 100 between two adjacent bit lines 120 among the bit lines 120. A lower contact CP may be electrically connected to the first active region A1 of the substrate 100. The lower contact CP may include, for example, polysilicon doped with impurities.

A lower end of the lower contact CP may be disposed at a level lower than the upper surface of the substrate 100, and may be disposed at a level higher than the lower surface of the bit line contact pattern DC. An upper surface of the lower contact CP may be disposed lower than a bottom surface of the bit line capping pattern 125 of the bit line structure BLS. The lower contact CP may be insulated from the bit line contact pattern DC by the bit line contact spacer 155.

A landing pad LP may be disposed on the lower contact CP. The landing pad LP may be electrically connected to the first active region A1 of the substrate 100 through the lower contact CP. An upper surface of the landing pad LP may be disposed higher than upper surfaces of the bit line structures BLS, and a bottom surface of the landing pad LP may be disposed lower than the upper surfaces of the bit line structures BLS. For example, the bottom surface of the landing pad LP may be disposed lower than an upper surface of the metal pattern 123 of the bit line 120. The landing pad LP may include a barrier layer 157 and a pad metal pattern 159 that are sequentially stacked. According to some embodiments, a contact silicide pattern may be provided between the lower contact CP and the landing pad LP.

A spacer structure 130 may be disposed between the bit line structures BLS and the lower contact CP. The spacer structure 130 may extend in the second direction DR2 along sidewalls of the bit line structures BLS. The spacer structure 130 may include a first spacer 131, a second spacer 132, a third spacer 133 and a fourth spacer 134. The first spacer 131 may be directly disposed on sidewalls of the bit line structures BLS. The second spacer 132 may be disposed between the first spacer 131 and the lower contact CP. The third spacer 133 may be disposed between the second spacer 132 and the lower contact CP. The second spacer 132 may be disposed between the first spacer 131 and the third spacer 133. The first spacer 131 and the third spacer 133 may include an insulating material having etching selectivity with respect to the lower insulation layer 110.

The second spacer 132 may include an insulating material having a lower dielectric constant than the first spacer 131 and the third spacer 133. For example, the first spacer 131 and the third spacer 133 may include a silicon nitride layer, and the second spacer 132 may include a silicon oxide layer. As another example, the second spacer 132 may include air. That is, the second spacer 132 may be an air spacer defined between sidewalls of the first spacer 131 and the third spacer 133. The fourth spacer 134 may be provided on an upper surface of the second spacer 132 and on a side surface of the first spacer 131. The fourth spacer 134 may surround a lower portion of the landing pad LP. In a plan view, the fourth spacer 134 may have a ring shape.

An insulation pattern 161 may be in (e.g., may fill) the space between landing pads LP. The insulation pattern 161 may surround sidewalls of the landing pads LP. As shown in FIG. 4, the insulation pattern 161 may be disposed within a first trench TR1 between the sidewalls of the landing pads LP. The first trench TR1 may be a node isolation trench electrically separating each of the landing pads LP. The landing pads LP may be spaced apart from each other interposing the first trench TR1. The first trench TR1 may have an inner side surface defined by surfaces of the landing pads LP, bit line capping patterns 125, and the spacer structure 130. For example, the insulation pattern 161 may include silicon nitride.

Capacitors CAP may be disposed on the landing pads LP. The capacitors CAP may be electrically connected to the landing pads LP, respectively. Each of the capacitors CAP may include a lower electrode BE, an upper electrode UE, and a dielectric layer DL therebetween. Each of the lower electrode BE and the upper electrode UE may include, for example, at least one of titanium, tantalum, tungsten, copper or aluminum.

The lower electrode BE and the upper electrode UE may include doped silicon, Ru, RuO, Pt, PtO, Ir, IrO, SRO(SrRuO), BSRO((Ba,Sr)RuO), CRO(CaRuO), BaRuO, La(Sr,Co)O, Ti, TiN, W, WN, Ta, TaN, TiAlN, TiSiN, TaAlN, TaSiN, or a combination thereof, respectively. The dielectric layer DL may include, for example, hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate or a combination thereof.

A capacitor contact via 420 connected to the capacitor CAP by penetrating (i.e., extending into) a first insulation layer IL1, and the first insulation layer IL1 on the capacitor CAP may be provided. The capacitor contact via 420 may be connected to the upper electrode UE of the capacitor CAP.

A cell signal wiring 430 may be disposed on the first insulation layer IL1. The cell signal wiring 430 may be disposed on the capacitor contact via 420, and electrically connected to the capacitor contact via 420. The cell signal wiring 430 may be electrically connected to the capacitor CAP through the capacitor contact via 420. The upper electrode UE of the capacitor CAP may receive a predetermined voltage through the cell signal wiring 430.

The core region COR may include a gate stack 200, a gate spacer structure 240, a first interlayer insulation layer 207, a second interlayer insulation layer 209 including a second trench TR2, a contact via 251, peripheral circuit wirings, wiring insulation patterns 261b, an etch stop layer SL, the first insulation layer IL1, a first contact plug 500, and a first core circuit wiring 512.

The gate stack 200 may be disposed on the first surface S1 of the substrate 100 of the core region COR. The gate stack 200 may extend in a direction parallel to the upper surface of the substrate 100. For example, in a plan view, the gate stack 200 may have the shape of a bar. The gate stack 200 may be disposed on second active regions A21 and A22 formed in the upper portion of the substrate 100. The second active regions A21 and A22 may be a region doped with impurities of N-type or P-type, and defined by a second isolation layer 101b.

Impurity regions 201 may be formed in the upper portion of the substrate 100. The impurity regions 201 may include impurities of different conductivity type from impurities doped to the second active regions A21 and A22. The impurity regions 201 may be a pair of source region and drain region electrically connected or separated according to the voltage applied to the gate stack 200. The impurity regions 201 may be spaced apart from each other interposing the gate stack 200. Each of the impurity regions 201 may be disposed adjacent to both lateral sides of the gate stack 200. For example, the gate stack 200 and the impurity regions 201 may configure a PMOS transistor, and the impurity regions 201 may be P-type impurity regions. The impurity regions 201 may include, for example, at least one of boron (B), aluminum (Al), gallium (Ga) or indium (In) elements. As another example, the gate stack 200 and the impurity regions 201 may configure an NMOS transistor, and the impurity regions 201 may be N-type impurity regions. The impurity regions 201 may include, for example, at least one of phosphorus (P), arsenic (As) or antimony (Sb) elements.

The PMOS transistor and the NMOS transistor of the core region COR may be one of driving transistors CTR1, CTR2, and CTR3 to be described later.

The gate stack 200 may include a gate insulation layer 210, a gate electrode 220 and a gate capping pattern 230. The gate insulation layer 210 may be interposed between the upper surface of the substrate 100 and the gate electrode 220. The gate capping pattern 230 may be disposed on an upper surface of the gate electrode 220.

The gate insulation layer 210 may include a dielectric material. According to some embodiments, the gate insulation layer 210 may include a first dielectric layer and a second dielectric layer on the first dielectric layer. The first dielectric layer may have a dielectric constant lower than the second dielectric layer. The first dielectric layer may include, for example, one of a silicon oxide layer or a silicon oxynitride layer. The second dielectric layer may include a high-k material having a high dielectric constant compared to a silicon oxide layer and/or a silicon oxynitride layer. The second dielectric layer may include, for example, one of oxide, nitride, silicide, oxynitride that includes one of hafnium (Hf), aluminum (Al), zirconium (Zr), or lanthanum (La).

The gate electrode 220 may include a work function adjustment layer 225, a first conductive layer 221, a second conductive layer 222 and a third conductive layer 223 that are sequentially stacked. The work function adjustment layer 225 may adjust threshold voltage of a transistor. According to some embodiments, the work function adjustment layer 225 may have a thicker thickness compared to the gate insulation layer 210. The work function adjustment layer 225 may include at least one of a P-type metal layer or an N-type metal layer. The work function adjustment layer 225 may include, for example, at least one of Ti, Ta, Al, Ni, Co, La, Pd, Nb, Mo, Hf, Ir, Ru, Pt, Yb, Dy, Er, Pd, TiAl, HfSiMo, TiN, WN,TaN, RuN, MoN, TiAlN, TaC, TiC, or TaC. The work function adjustment layer 225 may further include, for example, at least one of La/TiN, Mg/TiN, or Sr/TiN.

The first conductive layer 221 may include a doped semiconductor material. The first conductive layer 221 may include, for example, polysilicon. The first conductive layer 221 may be doped by, for example, P-type dopant.

The second conductive layer 222 may be disposed between the first conductive layer 221 and the third conductive layer 223. The second conductive layer 222 may have a thinner thickness compared to the first conductive layer 221 and the third conductive layer 223. The second conductive layer 222 may include silicide formed on an interface of the first conductive layer 221 and the third conductive layer 223. The second conductive layer 222 may include, for example, one of titanium silicide, cobalt silicide, nickel silicide, tungsten silicide, platinum silicide, or molybdenum silicide.

The third conductive layer 223 may include a metal material. The third conductive layer 223 may include, for example, at least one of W, Ti, or Ta.

The gate capping pattern 230 may be disposed on the upper surface of the gate electrode 220. The gate capping pattern 230 may formed to be on (e.g., to cover) an upper surface of the third conductive layer 223 to protect the gate electrode 220. The gate capping pattern 230 may include an insulating material. The gate capping pattern 230 may include, for example, silicon nitride.

The gate spacer structure 240 may be disposed on side surfaces of the gate stack 200. The gate spacer structure 240 may include a first gate spacer 241, a second gate spacer 242, and a third gate spacer 243.

The first gate spacer 241 may be disposed on a side surface of the gate stack 200. The first gate spacer 241 may vertically extend along the side surfaces of the gate stack 200. The first gate spacer 241 may have a lower oxygen element content ratio compared to the second gate spacer 242. The first gate spacer 241 may have a first dielectric constant, and the first dielectric constant may have a value in the range of 6.5 to 7.5. The first gate spacer 241 may include a material having etching selectivity with the first dielectric layer of the gate insulation layer 210. The first gate spacer 241 may include, for example, silicon nitride. An upper surface of the first gate spacer 241 may be coplanar with an upper surface of the gate capping pattern 230. The first gate spacer 241 may be directly disposed on a side surface of the gate electrode 220 and a side surface of the gate capping pattern 230.

The second gate spacer 242 may be disposed on the first gate spacer 241. The second gate spacer 242 may have a larger width compared to the first gate spacer 241. A width of the second gate spacer 242 may decrease away from the upper surface of the substrate 100. The second gate spacer 242 may include, for example, silicon oxide.

The third gate spacer 243 may be provided on the second gate spacer 242. The third gate spacer 243 may extend onto an upper surface of the gate stack 200 to be on (e.g., to cover) the upper surface of the first gate spacer 241 and the upper surface of the gate capping pattern 230. The third gate spacer 243 may extend onto the upper surface of the substrate 100.

The first interlayer insulation layer 207 may be disposed on the first surface S1 of the substrate 100. The first interlayer insulation layer 207 may not cover sidewalls of the gate spacer structure 240, and an upper surface of the gate spacer structure 240. An upper surface of the first interlayer insulation layer 207 may be coplanar with an upper surface of the third gate spacer 243. The first interlayer insulation layer 207 may include a high-density plasma (HDP) oxide layer, or a silicon oxide layer formed by a flowable CVD (FCVD) method. The second interlayer insulation layer 209 may be disposed on the first interlayer insulation layer 207. A lower surface of the second interlayer insulation layer 209 may be on (e.g., may cover) the upper surface of the third gate spacer 243. The second interlayer insulation layer 209 may include silicon nitride.

The first core circuit wiring 512 may be disposed on the second interlayer insulation layer 209. The first core circuit wiring 512 disposed in the core region COR may be disposed at the same level as the pad metal pattern 159 of the landing pad LP disposed in the cell array region CAR. The core circuit wiring 512 may be formed by a same process by using the same material as the pad metal pattern 159. The core circuit wiring 512 may be connected to the impurity regions 201 through a contact via 251. The contact via 251 and the core circuit wiring 512 may include, for example, at least one of copper (Cu), tungsten (W), aluminum (Al), tantalum (Ta), or titanium (Ti). The contact via 251 may penetrate (i.e., extend into) the first interlayer insulation layer 207 and the second interlayer insulation layer 209 and be connected to the substrate 100. According to some embodiments, a lower end of the contact via 251 may be disposed at a level lower than the upper surface of the substrate 100. The contact via 251 may be electrically connected between the core circuit wiring 512 and the impurity regions 201.

A contact barrier layer 253 may be on (e.g., may cover) a surface of the core circuit wiring 512 and the contact via 251. The contact barrier layer 253 may be provided between a lower surface of the core circuit wiring 512 and the second interlayer insulation layer 209. The contact barrier layer 253 may be provided on side surfaces and lower surfaces of the contact vias 251. The contact barrier layer 253 may include metal nitride. The contact barrier layer 253 may include, for example, one of titanium nitride (TiN), tantalum nitride (TaN) or tungsten nitride (WN).

The second trench TR2 may be formed between core circuit wirings 512. The second trench TR2 may be formed between sidewalls of the core circuit wirings 512, and may be formed to a predetermined depth from an upper surface of the second interlayer insulation layer 209. A lower end of the second trench TR2 may be disposed at a higher level than the upper surface of the gate capping pattern 230.

As an example, the second trench TR2 may be disposed at a place perpendicularly overlapping the gate stack 200 (i.e., vertically overlapping the gate stack 200) or disposed at a place vertically overlapping the second isolation layer 101b between the gate stacks 200.

A wiring insulation pattern 261b may be in (e.g., may fill) the second trench TR2. As an example, the wiring insulation pattern 261b may include silicon nitride.

The etch stop layer SL may be provided to be on (e.g., to cover) the insulation pattern 161, the wiring insulation pattern 261b, and the core circuit wirings 512. The first insulation layer IL1 may be disposed on the etch stop layer SL. The first contact plug 500 may be disposed to penetrate (i.e., extend into) the first insulation layer IL1 and the etch stop layer SL, and be connected to the core circuit wirings 512. The first contact plug 500 disposed in the core region COR may be disposed at the same level as the capacitor contact via 420 disposed in the cell array region CAR. The first contact plug 500 may be formed by a same process by using the same material as the capacitor contact via 420.

A first core signal wiring 510 may be disposed on the first insulation layer IL1. The first core signal wiring 510 may be disposed on the first contact plug 500, and electrically connected to the first contact plug 500. The first core signal wiring 510 may be electrically connected to the core circuit wiring 512 through the first contact plug 500. The core circuit wiring 512 may receive a predetermined signal through the first core signal wiring 510. The first core signal wiring 510 disposed in the core region COR may be disposed at the same level as the cell signal wiring 430 disposed in the cell array region CAR. The first core signal wiring 510 may be formed by a same process by using the same material as the cell signal wiring 430.

On a second surface S2 of the substrate 100, a second insulation layer IL2 may be disposed, and a second contact plug 600 may be disposed to penetrate (i.e., extend into) the substrate 100 and the second insulation layer IL2. A second core signal wiring 610 connected to the second contact plug 600 may be disposed on the second insulation layer IL2.

The first contact plug 500 may be connected to a first driving transistor of the second active region A21 among a plurality of driving transistors consisting of an impurity region 201 and the gate stack 200 disposed in the core region COR, and the second contact plug 600 may be connected to a second driving transistor of a second active region A22 among the plurality of driving transistors disposed in the core region COR.

A first signal applied to the first core signal wiring 510 connected to the first contact plug 500 may be applied to a first driving transistor of the second active region A21 through the first contact plug 500, and a second signal applied to the second core signal wiring 610 connected to the second contact plug 600 may be applied to a second driving transistor of the second active region A22 through the second contact plug 600. For example, the first signal may be a data signal, and the second signal may be a power signal, but are not limited thereto.

As shown in FIG. 5 and FIG. 6, the substrate 100 may further include the connection region CTR.

Referring to FIG. 5 and FIG. 6, in the connection region CTR, a first penetration portion TSV1 and a second penetration portion TSV2 may be disposed to penetrate (i.e., extend into) the substrate 100, the first insulation layer IL1 disposed on the first surface S1 of the substrate 100, and the second insulation layer IL2 disposed on the second surface S2 facing the first surface S1 of the substrate 100. That is, the first surface S1 and the second surface S2 of the substrate 100 may be opposite to each other.

As shown in FIG. 5, the first penetration portion TSV1 may include a first penetration electrode portion TSV11 (also referred to as a first penetration electrode TSV11) and a first insulation spacer TSV12. The first penetration electrode portion TSV11 of the first penetration portion TSV1 may vertically extend to penetrate (i.e., extend into) the substrate 100, the first insulation layer IL1, and the second insulation layer IL2, and the first insulation spacer TSV12 may be disposed on a sidewall of the first penetration electrode portion TSV11. The first penetration electrode portion TSV11 may include a conductive layer, and the first insulation spacer TSV12 may include a silicon-based insulating material such as silicon oxide or silicon nitride. The sidewall of the first penetration electrode portion TSV11 may be insulated by the first insulation spacer TSV12.

A third insulation layer IL11 may be disposed on the first insulation layer IL1 of the substrate 100, and within the third insulation layer IL11, a first connection pattern portion and a first pad portion PDA1 connected to the first connection pattern portion may be disposed. The first connection pattern portion may be connected to the first penetration electrode portion TSV11 of the first penetration portion TSV1.

The first connection pattern portion may include a plurality of connection wire layers 510A, 510B, 510C, 510D, and 510E and a plurality of connection vias 511A, 511B, 511C, and 511D (also referred to as a plurality of vias 511A, 511B, 511C, and 511D). The plurality of connection wire layers 510A, 510B, 510C, 510D, and 510E may be connected through the plurality of connection vias 511A, 511B, 511C, and 511D.

The first contact plug 500 penetrating (i.e., extending in) the first insulation layer IL1 disposed in the core region COR may be connected to a first driving transistor CTR1 disposed on the first surface S1 of the substrate 100, and the first contact plug 500 may be connected to a plurality of connection wiring portions disposed within the third insulation layer IL11. For example, the first contact plug 500 may be connected to the first penetration electrode portion TSV11 of the first penetration portion TSV1 through the first connection pattern portion disposed within the third insulation layer IL11. For example, the first connection pattern portion may be connected between the first contact plug 500 and the first penetration electrode portion TSV11 of the first penetration portion TSV1.

A fourth insulation layer IL22 may be disposed on the second insulation layer IL2 of the substrate 100, and within the fourth insulation layer IL22, a second connection pattern portion 610A and a second pad portion PDA2 connected to the second connection pattern portion 610A may be disposed. The second connection pattern portion 610A may be connected to the first penetration electrode portion TSV11 of the first penetration portion TSV1.

The first pad portion PDA1 and the second pad portion PDA2 may maintain the electrical connection between the semiconductor chips 1000A, 1000B, 1000C, and 1000D stacked (see FIG. 1) by being connected to pad portions of an adjacent semiconductor chip. For example, the first penetration electrode portion TSV11 of the first penetration portion TSV1 may be electrically connected to an external pad portion of an adjacent semiconductor chip through the first pad portion PDA1 and/or the second pad portion PDA2.

The first signal may be applied to the first driving transistor CTR1 disposed on the first surface S1 of the substrate 100 through the first penetration portion TSV1, first connection pattern portions 510A, 510B, 510C, 510D, 510E, 511A, 511B, 511C, and 511D, the second connection pattern portion 610A, and the first contact plug 500. For example, the first driving transistor CTR1 may receive the first signal from the first penetration electrode portion TSV11 of the first penetration portion TSV1 through the first connection pattern portion 510A, 510B, 510C, 510D, 510E, 511A, 511B, 511C, and 511D (e.g., the first connection pattern portion 510A) and the first contact plug 500. For example, the first signal may be a data signal, but the present disclosure is not limited thereto.

As shown in FIG. 6, the second penetration portion TSV2 may include a second penetration electrode portion TSV21 (also referred to as a second penetration electrode TSV21) and a second insulation spacer TSV22. The second penetration electrode portion TSV21 of the second penetration portion TSV2 may vertically extend into the substrate 100, the first insulation layer IL1, and penetrate (i.e., extend into) the second insulation layer IL2, and the second insulation spacer TSV22 may be disposed on a sidewall of the second penetration electrode portion TSV21. The second penetration electrode portion TSV21 may include a conductive layer, and the second insulation spacer TSV22 may include a silicon-based insulating material such as silicon oxide or silicon nitride. The sidewall of the second penetration electrode portion TSV21 may be insulated by the second insulation spacer TSV22.

The third insulation layer IL11 may be disposed on the first insulation layer IL1 of the substrate 100, and within the third insulation layer IL11, third connection pattern portions 520A, 520B, 520C, 520D, 520E, and 521A and a third pad portion PDB1 connected to the third connection pattern portions 520A, 520B, 520C, 520D, 520E, and 521A may be disposed. The third connection pattern portions 520A, 520B, 520C, 520D, 520E, and 521A may be connected to the second penetration electrode portion TSV21 of the second penetration portion TSV2. The third connection pattern portions 520A, 520B, 520C, 520D, 520E, and 521A may be on the first insulation layer IL1.

The third connection pattern portions 520A, 520B, 520C, 520D, 520E, and 521A may include a plurality of connection wire layers 520A, 520B, 520C, 520D, and 520E and a plurality of connection vias 521A. The plurality of connection wire layers 520A, 520B, 520C, 520D, and 520E may be connected through the plurality of connection vias 521A.

The fourth insulation layer IL22 may be disposed on the second insulation layer IL2 of the substrate 100, and within the fourth insulation layer IL22, a fourth connection pattern portion 610B and a fourth pad portion PDB2 connected to the fourth connection pattern portion 610B may be disposed. The fourth connection pattern portion 610B may be connected to the second penetration electrode portion TSV21 of the second penetration portion TSV2.

The second contact plug 600 penetrating (i.e., extending in) the second insulation layer IL2 and the substrate 100 disposed in the core region COR may be connected to a second driving transistor CTR2 disposed on the first surface S1 of the substrate 100, and the second contact plug 600 may be connected to the fourth connection pattern portion 610B disposed within the fourth insulation layer IL22. For example, the second contact plug 600 may be connected to the second penetration electrode portion TSV21 of the second penetration portion TSV2 through the fourth connection pattern portion 610B disposed within the fourth insulation layer IL22.

The third pad portion PDB1 and the fourth pad portion PDB2 may maintain the electrical connection between the semiconductor chips 1000A, 1000B, 1000C, and 1000D stacked (see FIG. 1) by being connected to pad portions of an adjacent semiconductor chip.

For example, the second penetration electrode portion TSV21 of the second penetration portion TSV2 may be electrically connected to an external pad portion of an adjacent semiconductor chip through the third pad portion PDB1 and/or the fourth pad portion PDB2.

The second signal may be applied to the second driving transistor CTR2 disposed on the first surface S1 of the substrate 100 through the second penetration portion TSV2, the third connection pattern portions 520A, 520B, 520C, 520D, 520E, and 521A, the fourth connection pattern portion 610B, and the second contact plug 600. For example, the second driving transistor CTR2 may receive the second signal from the second penetration electrode portion TSV21 of the second penetration portion TSV2 through the fourth connection pattern portion 610B and the second contact plug 600. For example, the second signal may be a power signal, but the present disclosure is not limited thereto.

The semiconductor element 1001 of a semiconductor device according to some embodiments may include the cell array region CAR, the core region COR, and the connection region CTR, where the first signal may be applied to the first driving transistor CTR1 disposed in the core region COR through the first penetration portion TSV1 disposed in the connection region CTR and the first contact plug 500 disposed on the first surface S1 of the substrate 100, and the second signal may be applied to the second driving transistor CTR2 disposed in the core region COR through the second penetration portion TSV2 and the second contact plug 600 disposed on the second surface S2 of the substrate 100. For example, the second contact plug 600 may extend into the second surface S2 of the substrate 100.

A semiconductor device according to some embodiments may include the stacked plurality of semiconductor elements, and adjacent ones of the semiconductor elements may be electrically connected to each other through pad portions PDA1, PDA2, PDB1, and PDB2 connected to the first penetration portion TSV1 and the second penetration portion TSV2.

The second contact plug 600 disposed on the second surface S2 of the substrate 100 may also be formed when forming the connection pattern portion for connecting the stacked plurality of semiconductor elements, and accordingly, the second signal may be applied through the second surface S2 of the substrate 100 through the process for interconnecting the stacked plurality of semiconductor elements without an additional process.

As such, since the first signal may be applied through the first surface S1 of the substrate 100 and the second signal may be applied through the second surface S2 of the substrate 100, the area of the signal application portion for applying the first signal and the second signal may be reduced, and by applying the second signal that is a power signal through the second surface S2 of the substrate 100, a stable power signal may be applied while enlarging the regions occupied by the cell array region CAR formed on the first surface S1 of the substrate 100.

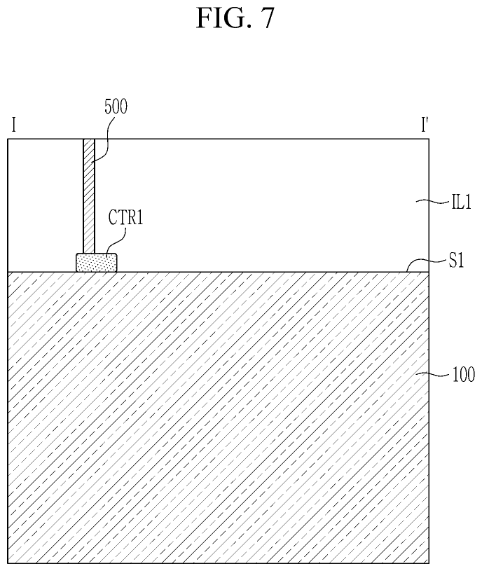

Next, with reference to FIGS. 7 to 16 together with FIGS. 1 to 6, a manufacturing method of a semiconductor device according to some embodiments will be described.

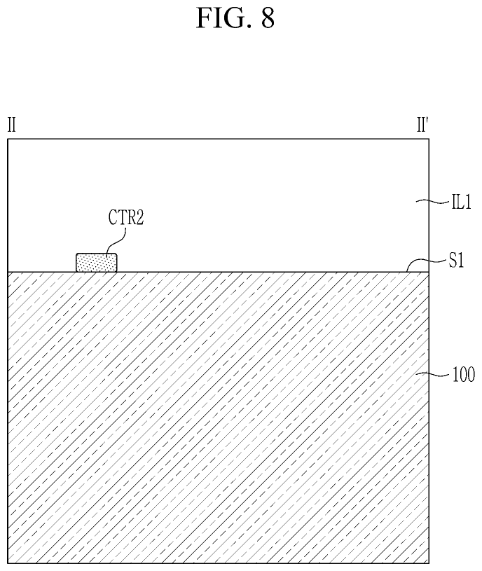

FIGS. 7 to 16 are cross-sectional views showing a manufacturing method of a semiconductor device according to some embodiments. In particular, FIGS. 7, 9, 11, 13, and 15 correspond to line I-I′ of FIG. 2, and FIGS. 8, 10, 12, 14, and 16 correspond to line II-II′ of FIG. 2.

Referring to FIG. 7 and FIG. 8, the first driving transistor CTR1 and the second driving transistor CTR2 may be formed on the first surface S1 of the substrate 100 disposed in the core region COR, the first insulation layer IL1 may be stacked on the first surface S1 of the substrate 100, and the first contact plug 500 may be formed to penetrate (i.e., extend into) the first insulation layer IL1 and be connected to the first driving transistor CTR1. At this time, a specific structure of the cell array region CAR and the core region COR disposed on the first surface S1 of the substrate 100 shown in FIG. 3 and FIG. 4 may be formed.

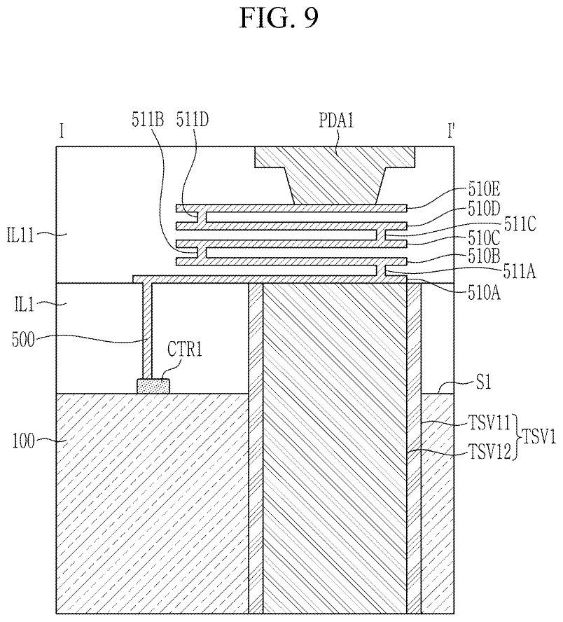

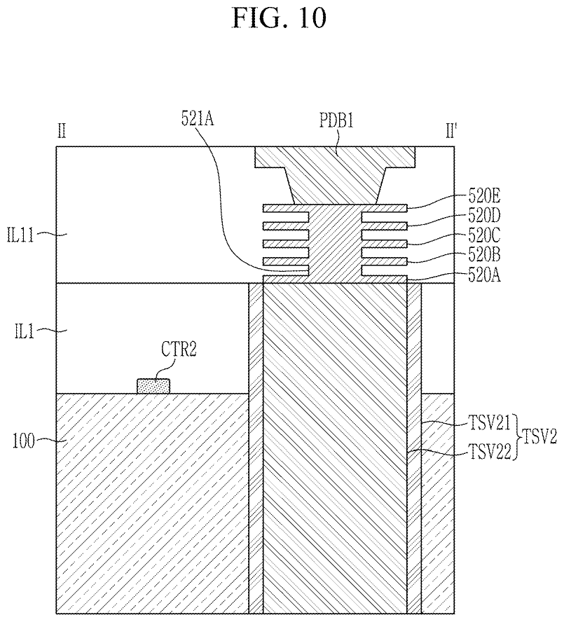

Referring to FIG. 9 and FIG. 10, the first penetration portion TSV1 and the second penetration portion TSV2 may be formed to penetrate (i.e., extend into) the substrate 100 and the first insulation layer IL1, the third insulation layer IL11 may be stacked on the first insulation layer IL1, the first connection pattern portions 510A, 510B, 510C, 510D, 510E, 511A, 511B, 511C, and 511D may be formed to be connected to the first contact plug 500 and the first penetration portion TSV1, the third connection pattern portions 520A, 520B, 520C, 520D, 520E, and 521A connected to the second penetration portion TSV2 may be formed, and the first pad portion PDA1 connected to the first connection pattern portions 510A, 510B, 510C, 510D, 510E, 511A, 511B, 511C, and 511D and the third pad portion PDB1 connected to the third connection pattern portions 520A, 520B, 520C, 520D, 520E, and 521A may be formed.

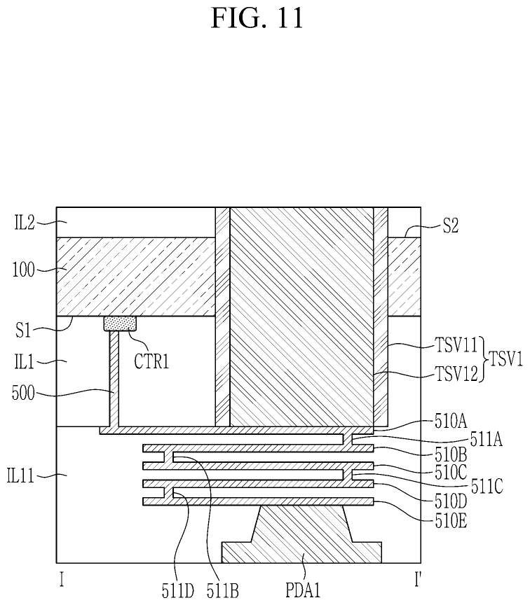

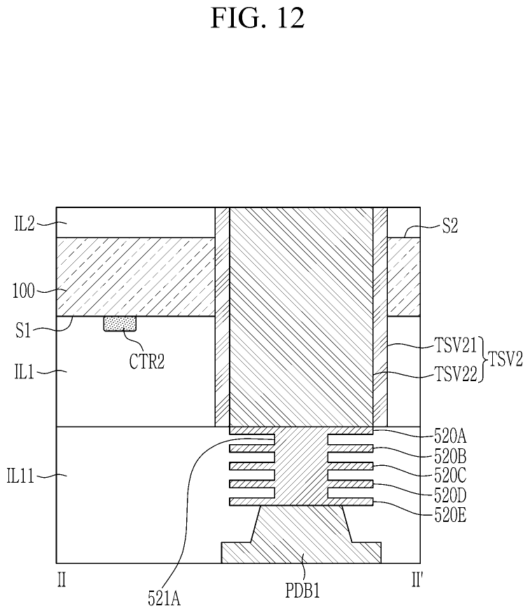

Referring to FIG. 11 and FIG. 12, the second surface S2 of the substrate 100 is formed by removing a portion of a surface opposite to the first surface S1 of the substrate 100, the first penetration portion TSV1 and the second penetration portion TSV2 are exposed on the second surface S2 of the substrate 100, and then the second insulation layer IL2 is stacked on side surfaces of an exposed portions of the first penetration portion TSV1 and the second penetration portion TSV2.

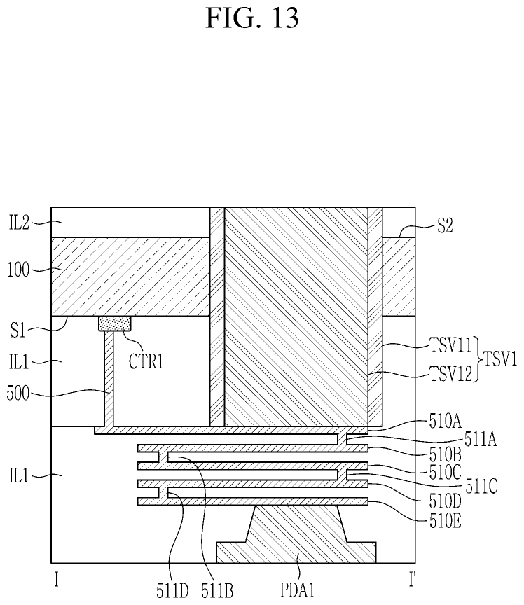

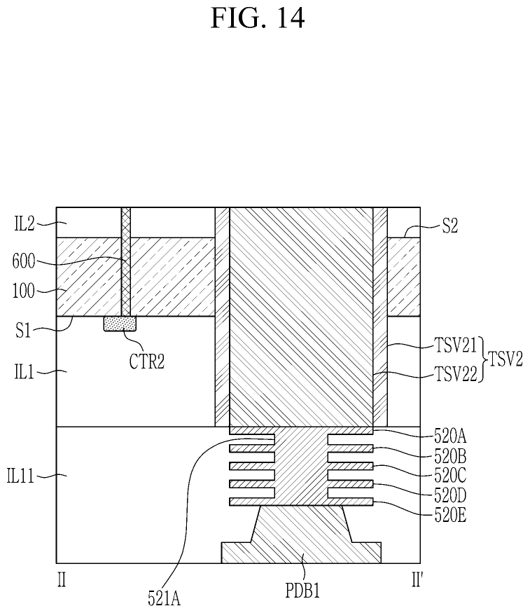

Referring to FIG. 13 and FIG. 14, the second contact plug 600 may be formed to penetrate (i.e., extend into) the substrate 100 and the second insulation layer IL2 and be connected to the second driving transistor CTR2.

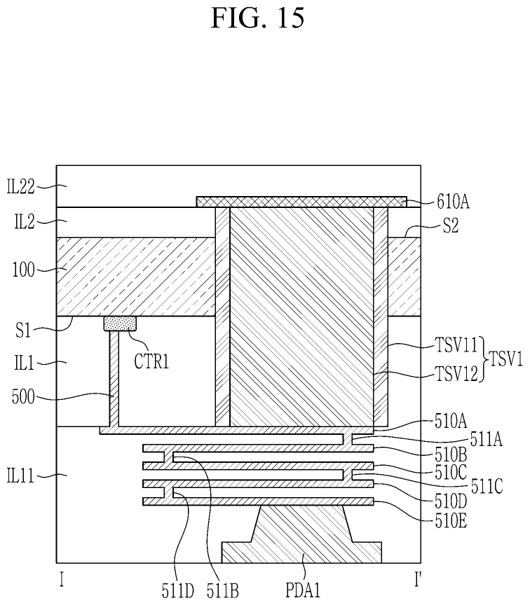

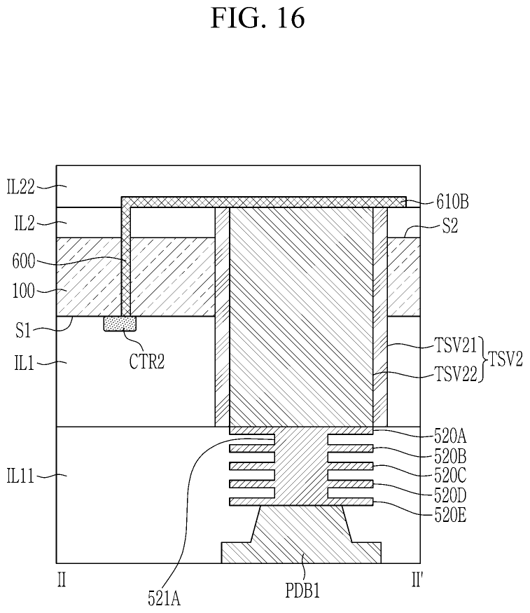

Referring to FIG. 15 and FIG. 16, the second connection pattern portion 610A connected to the first penetration portion TSV1 and the fourth connection pattern portion 610B connected to the second contact plug 600 and the second penetration portion TSV2 may be formed on the second insulation layer IL2 disposed on the second surface S2 of the substrate 100, and the fourth insulation layer IL22 may be stacked on the second insulation layer IL2.

Subsequently, by forming the second pad portion PDA2 and the fourth pad portion PDB2 connected to the second connection pattern portion 610A and the fourth connection pattern portion 610B in the fourth insulation layer IL22, respectively, as shown in FIGS. 1 to 6 (e.g., see FIGS. 5 and 6), the semiconductor element 1001 of a semiconductor device including the cell array region CAR, the core region COR, and the connection region CTR may be formed.

As described above, a semiconductor device according to some embodiments may include the stacked plurality of semiconductor elements, and adjacent ones of the semiconductor elements may be electrically connected to each other through the pad portions PDA1, PDA2, PDB1, and PDB2 connected to the first penetration portion TSV1 and the second penetration portion TSV2.

As such, during the process of forming the first penetration portion TSV1 and the second penetration portion TSV2 penetrating (i.e., extending into) the first surface S1 and the second surface S2 of the substrate 100, and a plurality of connection pattern portions and a plurality of pad portions PDA1, PDA2, PDB1, and PDB2 connected to the first penetration portion TSV1 and the second penetration portion TSV2, such that the first signal may be applied to the first driving transistor CTR1 disposed in the core region COR and the second signal may be applied to the second driving transistor CTR2 disposed in the core region COR, the process of forming the first connection pattern portions 510A, 510B, 510C, 510D, 510E, 511A, 511B, 511C, and 511D connected to the first contact plug 500 disposed on the first surface S1 of the substrate 100 and connected to the first penetration portion TSV1 and the fourth connection pattern portion 610B connected to the second contact plug 600 disposed on the second surface S2 of the substrate 100 and connected to the second penetration portion TSV2 may be performed together.

Therefore, without complicating the manufacturing process, the area of the signal application portion for applying the first signal and the second signal may be reduced, and by applying the second signal that is a power signal through the second surface S2 of the substrate 100, a stable power signal may be applied while enlarging the regions occupied by the cell array region CAR formed on the first surface S1 of the substrate 100.

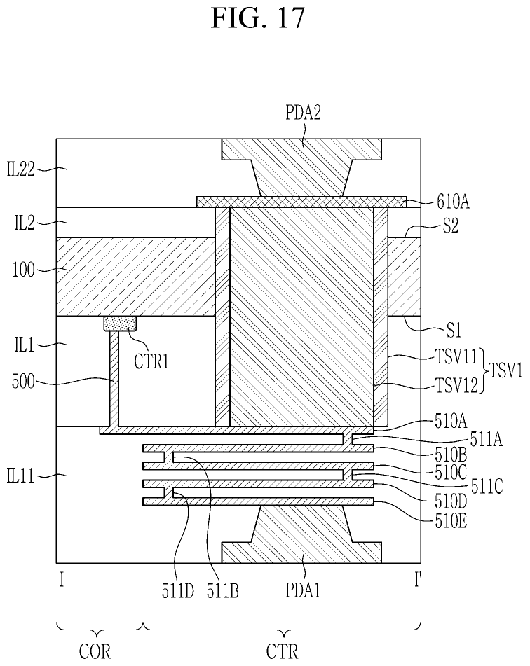

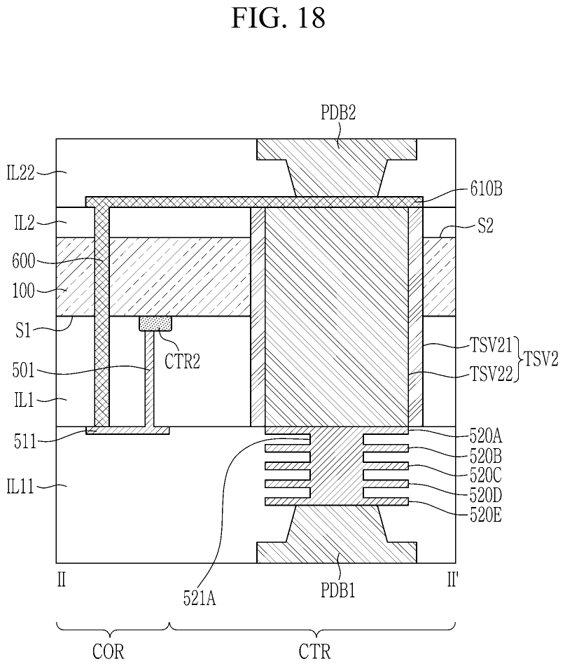

With reference to FIG. 17 and FIG. 18, a semiconductor device according to some other embodiments will be described. FIG. 17 is a cross-sectional view of a semiconductor device taken along line I-I′ of FIG. 2 according to some embodiments. FIG. 18 is a cross-sectional view of a semiconductor device taken along line II-II′ of FIG. 2 according to some embodiments.

As shown in FIG. 17, the third insulation layer IL11 may be disposed on the first insulation layer IL1 of the substrate 100, and within the third insulation layer IL11, the first connection pattern portions 510A, 510B, 510C, 510D, 510E, 511A, 511B, 511C, and 511D and the first pad portion PDA1 connected to the first connection pattern portions 510A, 510B, 510C, 510D, 510E, 511A, 511B, 511C, and 511D may be disposed. First connection pattern portion may be connected to the first penetration electrode portion TSV11 of the first penetration portion TSV1.

The first contact plug 500 penetrating (i.e., extending in) the first insulation layer IL1 disposed in the core region COR may be connected to the first driving transistor CTR1 disposed on the first surface S1 of the substrate 100, and the first contact plug 500 may be connected to the first connection pattern portion disposed within the third insulation layer IL11.

The fourth insulation layer IL22 may be disposed on the second insulation layer IL2 of the substrate 100, and within the fourth insulation layer IL22, the second connection pattern portion 610A and the second pad portion PDA2 connected to the second connection pattern portion 610A may be disposed. The second connection pattern portion 610A may be connected to the first penetration electrode portion TSV11 of the first penetration portion TSV1.

The first pad portion PDA1 and the second pad portion PDA2 may maintain the electrical connection between the semiconductor chips 1000A, 1000B, 1000C, and 1000D stacked (see FIG. 1) by being connected to pad portions of an adjacent semiconductor chip.

The first signal may be applied to the first driving transistor CTR1 disposed on the first surface S1 of the substrate 100 through the first penetration portion TSV1, the first connection pattern portions 510A, 510B, 510C, 510D, 510E, 511A, 511B, 511C, and 511D, the second connection pattern portion 610A, and the first contact plug 500. For example, the first signal may be a data signal, but the present disclosure is not limited thereto.

As shown in FIG. 18, the third insulation layer IL11 may be disposed on the first insulation layer IL1 of the substrate 100, and within the third insulation layer IL11, the third connection pattern portions 520A, 520B, 520C, 520D, 520E, and 521A and the third pad portion PDB1 connected to the third connection pattern portions 520A, 520B, 520C, 520D, 520E, and 521A may be disposed. The third connection pattern portions 520A, 520B, 520C, 520D, 520E, and 521A may be connected to the second penetration electrode portion TSV21 of the second penetration portion TSV2.

Unlike the embodiment shown in FIG. 6, according to the present embodiment, a third contact plug 501 connected to the second driving transistor CTR2 and a fifth connection pattern portion 511 disposed within the third insulation layer IL11, and disposed on the first insulation layer IL1 may be further included, as shown in FIG. 18. In addition, the second contact plug 600 may penetrate (i.e., extend into) the substrate 100, the first insulation layer IL1, and the second insulation layer IL2, and be connected to the fifth connection pattern portion 511 and the fourth connection pattern portion 610B.

The fourth insulation layer IL22 may be disposed on the second insulation layer IL2 of the substrate 100, and within the fourth insulation layer IL22, the fourth connection pattern portion 610B and the fourth pad portion PDB2 connected to the fourth connection pattern portion 610B may be disposed. The fourth connection pattern portion 610B may be connected to the second penetration electrode portion TSV21 of the second penetration portion TSV2.

The second driving transistor CTR2 disposed on the first surface S1 of the substrate 100 may be connected to the fourth connection pattern portion 610B connected to the second penetration portion TSV2 through the third contact plug 501, the fifth connection pattern portion 511, and the second contact plug 600.

The second signal may be applied to the second driving transistor CTR2 disposed on the first surface S1 of the substrate 100 through the second penetration portion TSV2, the third connection pattern portions 520A, 520B, 520C, 520D, 520E, and 521A, the fourth connection pattern portion 610B, the second contact plug 600, the third contact plug 501, and the fifth connection pattern portion 511. For example, the second signal may be a power signal, but the present disclosure is not limited thereto.

As such, in the semiconductor device according to some embodiments, the first signal may be applied to the first driving transistor CTR1 disposed in the core region COR through the first penetration portion TSV1 disposed in the connection region CTR and the first contact plug 500 disposed on the first surface S1 of the substrate 100.

In addition, through the second penetration portion TSV2, the second contact plug 600 disposed on the second surface S2 of the substrate 100, the third contact plug 501, and the fifth connection pattern portion 511, the second signal may be applied to the second driving transistor CTR2 disposed in the core region COR.

The semiconductor device according to some embodiments may include the stacked plurality of semiconductor elements, and adjacent ones of the semiconductor elements may be electrically connected to each other through the pad portions PDA1, PDA2, PDB1, and PDB2 connected to the first penetration portion TSV1 and the second penetration portion TSV2.

Various features of semiconductor devices according to embodiments described above with reference to FIGS. 1 to 16 may also be applied to the semiconductor device described with reference to FIGS. 17 and 18.

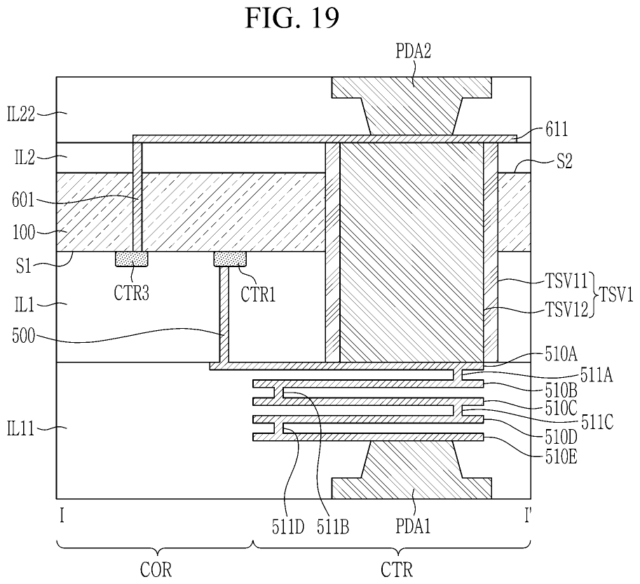

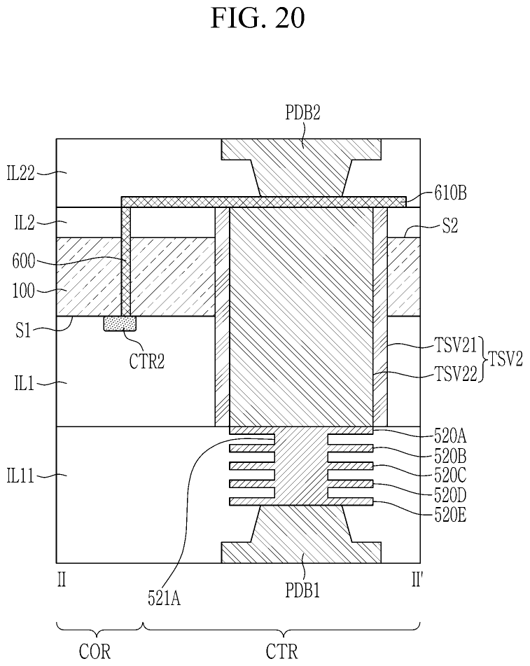

With reference to FIG. 19 and FIG. 20, a semiconductor device according to some other embodiments will be described. FIG. 19 is a cross-sectional view of a semiconductor device taken along line I-I′ of FIG. 2 according to some embodiments. FIG. 20 is a cross-sectional view of a semiconductor device taken along line II-II′ of FIG. 2 according to some embodiments.

As shown in FIG. 19, the third insulation layer IL11 may be disposed on the first insulation layer IL1 of the substrate 100, and within the third insulation layer IL11, the first connection pattern portions 510A, 510B, 510C, 510D, 510E, 511A, 511B, 511C, and 511D and the first pad portion PDA1 connected to the first connection pattern portions 510A, 510B, 510C, 510D, 510E, 511A, 511B, 511C, and 511D may be disposed. The first connection pattern portion may be connected to the first penetration electrode portion TSV11 of the first penetration portion TSV1.

The first contact plug 500 penetrating (i.e., extending in) the first insulation layer IL1 disposed in the core region COR may be connected to the first driving transistor CTR1 disposed on the first surface S1 of the substrate 100, and the first contact plug 500 may be connected to the first connection pattern portion disposed within the third insulation layer IL11.

The fourth insulation layer IL22 may be disposed on the second insulation layer IL2 of the substrate 100, and within the fourth insulation layer IL22, a sixth connection pattern portion 611 and the second pad portion PDA2 connected to the sixth connection pattern portion 611 may be disposed. The sixth connection pattern portion 611 may be connected to the first penetration electrode portion TSV11 of the first penetration portion TSV1.

The core region COR may further include a third driving transistor CTR3 and a fourth contact plug 601 connected to the third driving transistor CTR3 and penetrating (i.e., extending in) the substrate 100 and the second insulation layer IL2.

The fourth contact plug 601 may be connected to the sixth connection pattern portion 611. For example, the fourth contact plug 601 may be connected to the first penetration electrode portion TSV11 of the first penetration portion TSV1 through the sixth connection pattern portion 611.

The first pad portion PDA1 and the second pad portion PDA2 may maintain the electrical connection between the semiconductor chips 1000A, 1000B, 1000C, and 1000D stacked (see FIG. 1) by being connected to pad portions of an adjacent semiconductor chip.

The first signal may be applied to the first driving transistor CTR1 disposed on the first surface S1 of the substrate 100 through the first penetration portion TSV1, the first connection pattern portions 510A, 510B, 510C, 510D, 510E, 511A, 511B, 511C, and 511D, the sixth connection pattern portion 611, and the first contact plug 500. Simultaneously, the first signal may be applied to the third driving transistor CTR3 disposed on the first surface S1 of the substrate 100 through the first penetration portion TSV1, the sixth connection pattern portion 611, and the fourth contact plug 601. For example, the first signal may be a data signal, but the present disclosure is not limited thereto.

As shown in FIG. 20, the third insulation layer IL11 may be disposed on the first insulation layer IL1 of the substrate 100, and within the third insulation layer IL11, the third connection pattern portions 520A, 520B, 520C, 520D, 520E, and 521A and the third pad portion PDB1 connected to the third connection pattern portions 520A, 520B, 520C, 520D, 520E, and 521A may be disposed. The third connection pattern portions 520A, 520B, 520C, 520D, 520E, and 521A may be connected to the second penetration electrode portion TSV21 of the second penetration portion TSV2.

The third connection pattern portions 520A, 520B, 520C, 520D, 520E, and 521A may include the plurality of connection wire layers 520A, 520B, 520C, 520D, and 520E and the plurality of connection vias 521A. The plurality of connection wire layers 520A, 520B, 520C, 520D, and 520E may be connected through the plurality of connection vias 521A.

The fourth insulation layer IL22 may be disposed on the second insulation layer IL2 of the substrate 100, and within the fourth insulation layer IL22, the fourth connection pattern portion 610B and the fourth pad portion PDB2 connected to the fourth connection pattern portion 610B may be disposed. The fourth connection pattern portion 610B may be connected to the second penetration electrode portion TSV21 of the second penetration portion TSV2.

The second contact plug 600 penetrating (i.e., extending in) the second insulation layer IL2 and the substrate 100 disposed in the core region COR may be connected to the second driving transistor CTR2 disposed on the first surface S1 of the substrate 100, and the second contact plug 600 may be connected to the fourth connection pattern portion 610B disposed within the fourth insulation layer IL22.

The third pad portion PDB1 and the fourth pad portion PDB2 may maintain the electrical connection between the semiconductor chips 1000A, 1000B, 1000C, and 1000D stacked (see FIG. 1) by being connected to pad portions of an adjacent semiconductor chip.

The second signal may be applied to the second driving transistor CTR2 disposed on the first surface S1 of the substrate 100 through the second penetration portion TSV2, the third connection pattern portions 520A, 520B, 520C, 520D, 520E, and 521A, the fourth connection pattern portion 610B, and the second contact plug 600. For example, the second signal may be a power signal, but the present disclosure is not limited thereto.

As such, in the semiconductor device according to some embodiments, the first signal may be applied to the first driving transistor CTR1 disposed in the core region COR through the first penetration portion TSV1 disposed in the connection region CTR and the first contact plug 500 disposed on the first surface S1 of the substrate 100, and at the same time, the first signal may be applied to the third driving transistor CTR3 disposed in the core region COR through the first penetration portion TSV1 disposed in the connection region CTR and the fourth contact plug 601 and the sixth connection pattern portion 611 disposed on the second surface S2 of the substrate 100.

In addition, the second signal may be applied to the second driving transistor CTR2 disposed in the core region COR through the second penetration portion TSV2 and the second contact plug 600 disposed on the second surface S2 of the substrate 100.

The semiconductor device according to some embodiments may include the stacked plurality of semiconductor elements, and adjacent ones of the semiconductor elements may be electrically connected to each other through the pad portions PDA1, PDA2, PDB1, and PDB2 connected to the first penetration portion TSV1, and the second penetration portion TSV2.

Various features of semiconductor devices according to embodiments described above with reference to FIGS. 1 to 18 may also be applied to the semiconductor device described with reference to FIGS. 19 and 20.

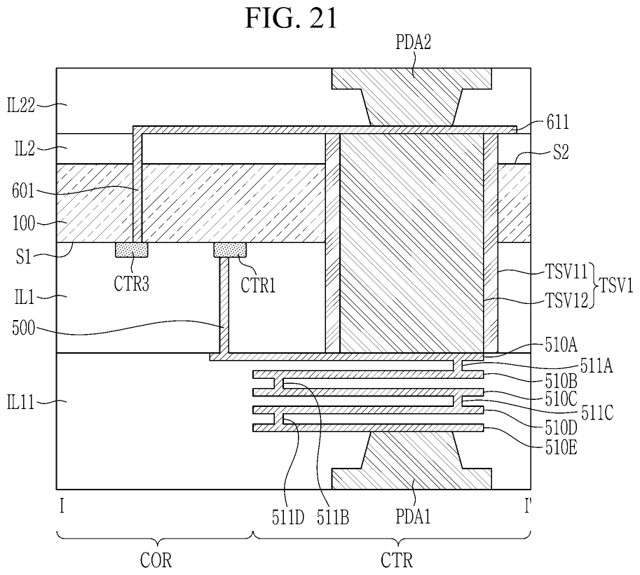

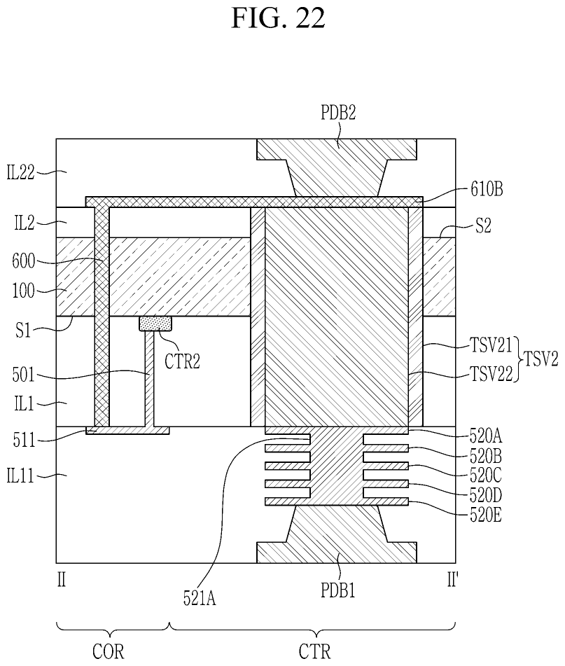

With reference to FIG. 21 and FIG. 22, a semiconductor device according to some other embodiments will be described. FIG. 21 is a cross-sectional view of a semiconductor device taken along line I-I′ of FIG. 2 according to some embodiments. FIG. 22 is a cross-sectional view of a semiconductor device taken along line II-II′ of FIG. 2 according to some embodiments.

Referring to FIG. 21, the third insulation layer IL11 may be disposed on the first insulation layer IL1 of the substrate 100, and within the third insulation layer IL11, the first connection pattern portions 510A, 510B, 510C, 510D, 510E, 511A, 511B, 511C, and 511D and the first pad portion PDA1 connected to the first connection pattern portions 510A, 510B, 510C, 510D, 510E, 511A, 511B, 511C, and 511D may be disposed. The first connection pattern portion may be connected to the first penetration electrode portion TSV11 of the first penetration portion TSV1.

The first contact plug 500 penetrating (i.e., extending in) the first insulation layer IL1 disposed in the core region COR may be connected to the first driving transistor CTR1 disposed on the first surface S1 of the substrate 100, and the first contact plug 500 may be connected to the first connection pattern portion disposed within the third insulation layer IL11.

The fourth insulation layer IL22 may be disposed on the second insulation layer IL2 of the substrate 100, and within the fourth insulation layer IL22, the sixth connection pattern portion 611 and the second pad portion PDA2 connected to the sixth connection pattern portion 611 may be disposed. The sixth connection pattern portion 611 may be connected to the first penetration electrode portion TSV11 of the first penetration portion TSV1.

The core region COR may further include the third driving transistor CTR3 and the fourth contact plug 601 connected to the third driving transistor CTR3 and penetrating (i.e., extending in) the substrate 100 and the second insulation layer IL2.

The fourth contact plug 601 may be connected to the sixth connection pattern portion 611.

The first pad portion PDA1 and the second pad portion PDA2 may maintain the electrical connection between the semiconductor chips 1000A, 1000B, 1000C, and 1000D stacked (see FIG. 1) by being connected to pad portions of an adjacent semiconductor chip.

The first signal may be applied to the first driving transistor CTR1 disposed on the first surface S1 of the substrate 100 through the first penetration portion TSV1, the first connection pattern portions 510A, 510B, 510C, 510D, 510E, 511A, 511B, 511C, and 511D, the sixth connection pattern portion 611, and the first contact plug 500. Simultaneously, the first signal may be applied to the third driving transistor CTR3 disposed on the first surface S1 of the substrate 100 through the first penetration portion TSV1, the sixth connection pattern portion 611, and the fourth contact plug 601. For example, the first signal may be a data signal, but the present disclosure is not limited thereto.

Referring to FIG. 22, the third insulation layer IL11 may be disposed on the first insulation layer IL1 of the substrate 100, and within the third insulation layer IL11, the third connection pattern portions 520A, 520B, 520C, 520D, 520E, and 521A and the third pad portion PDB1 connected to the third connection pattern portions 520A, 520B, 520C, 520D, 520E, and 521A may be disposed. The third connection pattern portions 520A, 520B, 520C, 520D, 520E, and 521A may be connected to the second penetration electrode portion TSV21 of the second penetration portion TSV2.

According to some embodiments, the third contact plug 501 connected to the second driving transistor CTR2 and the fifth connection pattern portion 511 disposed within the third insulation layer IL11, and disposed on the first insulation layer IL1, may be further included. In addition, the second contact plug 600 may penetrate (i.e., extend into) the substrate 100, the first insulation layer IL1, and the second insulation layer IL2, and be connected to the fifth connection pattern portion 511 and the fourth connection pattern portion 610B.

The fourth insulation layer IL22 may be disposed on the second insulation layer IL2 of the substrate 100, and within the fourth insulation layer IL22, the fourth connection pattern portion 610B and the fourth pad portion PDB2 connected to the fourth connection pattern portion 610B may be disposed. The fourth connection pattern portion 610B may be connected to the second penetration electrode portion TSV21 of the second penetration portion TSV2.

The second driving transistor CTR2 disposed on the first surface S1 of the substrate 100 may be connected to the fourth connection pattern portion 610B connected to the second penetration portion TSV2 through the third contact plug 501, the fifth connection pattern portion 511, and the second contact plug 600.

The second signal may be applied to the second driving transistor CTR2 disposed on the first surface S1 of the substrate 100 through the second penetration portion TSV2, the third connection pattern portions 520A, 520B, 520C, 520D, 520E, and 521A, the fourth connection pattern portion 610B, the second contact plug 600, the third contact plug 501, and the fifth connection pattern portion 511. For example, the second signal may be a power signal, but the present disclosure is not limited thereto.

As such, in the semiconductor device according to some embodiments, the first signal may be applied to the first driving transistor CTR1 disposed in the core region COR through the first penetration portion TSV1 disposed in the connection region CTR and the first contact plug 500 disposed on the first surface S1 of the substrate 100, and at the same time, the first signal may be applied to the third driving transistor CTR3 disposed in the core region COR through the first penetration portion TSV1 disposed in the connection region CTR and the fourth contact plug 601 and the sixth connection pattern portion 611 disposed on the second surface S2 of the substrate 100.

In addition, through the second penetration portion TSV2, the second contact plug 600 disposed on the second surface S2 of the substrate 100, the third contact plug 501, and the fifth connection pattern portion 511, the second signal may be applied to the second driving transistor CTR2 disposed in the core region COR.

The semiconductor device according to some embodiments may include the stacked plurality of semiconductor elements, and adjacent ones of the semiconductor elements may be electrically connected to each other through the pad portions PDA1, PDA2, PDB1, and PDB2 connected to the first penetration portion TSV1 and the second penetration portion TSV2.

Various features of semiconductor devices according to embodiments described above with reference to FIGS. 1 to 20 may also be applied to the semiconductor device described with reference to FIGS. 21 and 22.

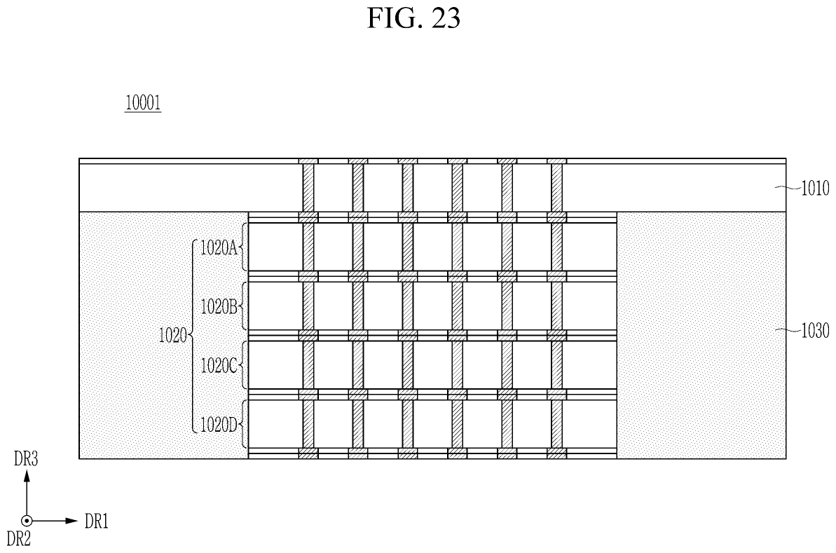

With reference to FIG. 23, a semiconductor device according to some other embodiments will be described. FIG. 23 is a schematic drawing showing a semiconductor device according to some embodiments.

Referring to FIG. 23, a semiconductor device 10001 according to some embodiments may include a semiconductor chip stacking structure 1020, a top die 1010 and a molding material 1030.

The semiconductor chip stacking structure 1020 may have a structure in which a plurality of semiconductor chips 1020A, 1020B, 1020C, and 1020D are stacked in one direction (e.g., the third direction DR3). The top die 1010 may be disposed on the semiconductor chip stacking structure 1020. In some embodiments, the top die 1010 may have a larger width in the first direction DR1 compared to the semiconductor chip stacking structure 1020.

Each of the plurality of semiconductor chips 1020A, 1020B, 1020C, and 1020D stacked in the semiconductor chip stacking structure 1020 may be a semiconductor memory chip. The top die 1010 may be a buffer die or a logic die. For example, the top die 1010 may be a central processing unit (CPU) chip, a graphic processing unit (GPU) chip or an application processor (AP) chip.

The semiconductor chip stacking structure 1020 and the top die 1010 may be bonded by hybrid bonding.

Various features of semiconductor devices according to embodiments described above with reference to FIGS. 1 to 22 may also be applied to the semiconductor device 10001 described with reference to FIG. 23.

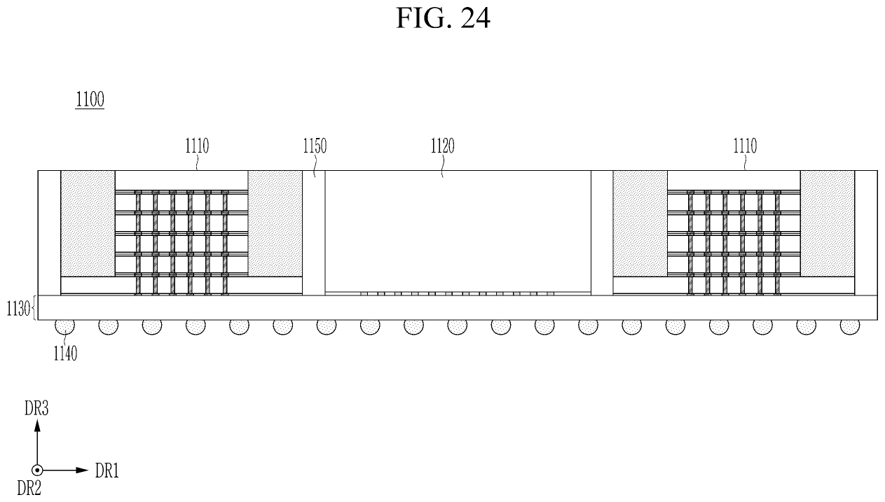

With reference to FIG. 24, a semiconductor device according to some other embodiments will be described. FIG. 24 is a schematic drawing showing a semiconductor device according to some embodiments.

Referring to FIG. 24, a semiconductor device 1100 according to some embodiments may include a plurality of first semiconductor chips 1110 and a second semiconductor chip 1120, an interposer 1130, and a molding material 1150. A first semiconductor chip 1110 may include the semiconductor stacking structure, bottom die, and molding material described with reference to FIG. 1. The second semiconductor chip 1120 may be a logic die.

A substrate (not shown) may be disposed in a lower portion of the interposer 1130. Connection members may be disposed on a bottom surface of the interposer 1130. In some embodiments, the interposer 1130 may include a silicon interposer.

The first semiconductor chips 1110 and the second semiconductor chip 1120 may be disposed on the interposer 1130. The first semiconductor chips 1110 and the second semiconductor chip 1120 may be coupled to the interposer 1130 by hybrid bonding. The second semiconductor chip 1120 may include connection pads and an insulation layer for hybrid bonding.

The second semiconductor chip 1120 may be disposed side-by-side to the first semiconductor chips 1110 between the first semiconductor chips 1110. That is, the second semiconductor chip 1120 may be between the first semiconductor chips 1110. In some embodiments, the second semiconductor chip 1120 may include a system-on-chip (SoC). In some embodiments, the second semiconductor chip 1120 may include a central processing unit (CPU) or a graphic processing unit (GPU).

The molding material 1150 may be disposed on the interposer 1130, and mold the first semiconductor chips 1110 and the second semiconductor chip 1120.

Various features of semiconductor devices according to embodiments described above with reference to FIGS. 1 to 22 may also be applied to the semiconductor device 1100 described with reference to FIG. 24.

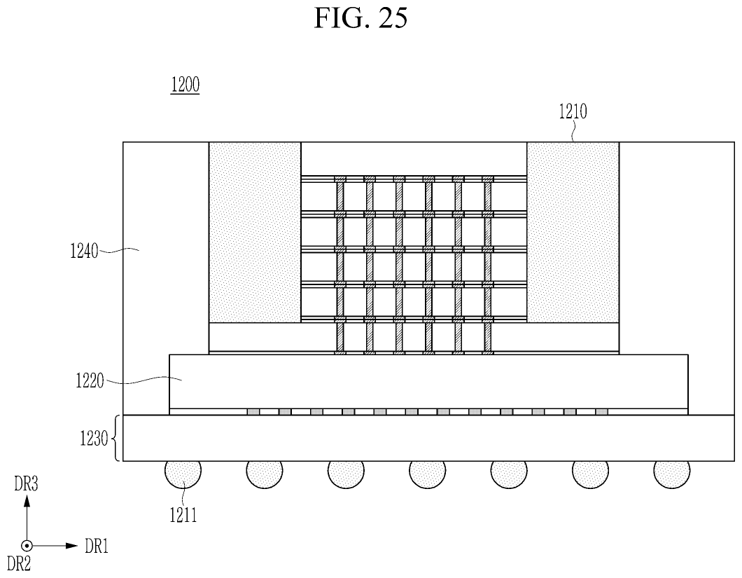

With reference to FIG. 25, a semiconductor device according to some other embodiments will be described. FIG. 25 is a cross-sectional view of a semiconductor device according to some embodiments.

Referring to FIG. 25, a semiconductor package 1200 may include a first semiconductor chip 1210, a second semiconductor chip 1220, an interposer 1230, and a molding material 1240. The first semiconductor chip 1210 may include the semiconductor stacking structure, bottom die and molding material described with reference to FIG. 1. The second semiconductor chip 1220 may be a logic die.

A substrate (not shown) may be disposed in a lower portion of the interposer 1230. Connection members may be disposed on a bottom surface of the interposer 1230. In some embodiments, the interposer 1230 may include a silicon interposer. The second semiconductor chip 1220 may be disposed on the interposer 1230. The second semiconductor chip 1220 may be coupled to the interposer 1230 by hybrid bonding.

In some embodiments, the second semiconductor chip 1220 may include a system-on-chip (SoC). In some embodiments, the second semiconductor chip 1220 may include a central processing unit (CPU) or a graphic processing unit (GPU).

The first semiconductor chip 1210 may be disposed on the second semiconductor chip 1220. The first semiconductor chip 1210 may be coupled to the second semiconductor chip 1220 by hybrid bonding.

The molding material 1240 may be disposed on the interposer 1230, and mold the first semiconductor chip 1210 and the second semiconductor chip 1220.

Various features of semiconductor devices according to embodiments described above with reference to FIGS. 1 to 22 may also be applied to the semiconductor device described with reference to FIG. 25.

While this disclosure has been described in connection with what is presently considered to be practical embodiments, it is to be understood that the invention is not limited to the disclosed embodiments, but, on the contrary, is intended to cover various modifications and equivalent arrangements included within the scope of the appended claims.

What is claimed is:

1. A semiconductor device, comprising:
a substrate that comprises a first surface and a second surface opposite to each other;
a first driving transistor and a second driving transistor on the first surface of the substrate;
a first insulation layer on the first surface of the substrate;
a second insulation layer on the second surface of the substrate;
a first penetration electrode and a second penetration electrode that extend into the substrate, the first insulation layer, and the second insulation layer;
a first contact plug extending in the first insulation layer and electrically connected to the first driving transistor and the first penetration electrode; and
a second contact plug extending in the substrate and the second insulation layer and electrically connected to the second driving transistor and the second penetration electrode.

2. The semiconductor device of claim 1, further comprising a first connection pattern portion on the first insulation layer,
wherein the first connection pattern portion is electrically connected between the first penetration electrode and the first contact plug.

3. The semiconductor device of claim 2, further comprising a second connection pattern portion on the second insulation layer and electrically connected to the first penetration electrode.

4. The semiconductor device of claim 3, wherein the first connection pattern portion comprises a plurality of connection wire layers and a plurality of vias, and
wherein ones of the plurality of vias are between ones of the plurality of connection wire layers.

5. The semiconductor device of claim 3, further comprising:
a third insulation layer on the first insulation layer; and
a fourth insulation layer on the second insulation layer,
wherein the first connection pattern portion is within the third insulation layer, and the second connection pattern portion is within the fourth insulation layer.

6. The semiconductor device of claim 5, further comprising:
a first pad portion electrically connected to the first connection pattern portion; and
a second pad portion electrically connected to the second connection pattern portion,
wherein the first penetration electrode is electrically connected to an external pad portion through one or more of the first pad portion and the second pad portion.

7. The semiconductor device of claim 6, wherein the first driving transistor is configured to receive a first signal from the first penetration electrode through the first contact plug and the first connection pattern portion, and
wherein the first contact plug is on the first surface of the substrate.

8. The semiconductor device of claim 1, further comprising:
a third driving transistor on the first surface of the substrate; and
a third contact plug extending in the substrate and the second insulation layer and electrically connected to the third driving transistor and the first penetration electrode.

9. The semiconductor device of claim 8, further comprising a first connection pattern portion on the second insulation layer and electrically connected between the first penetration electrode and the third contact plug.

10. The semiconductor device of claim 1, further comprising:
a first connection pattern portion on the first insulation layer and electrically connected to the second penetration electrode; and
a second connection pattern portion on the second insulation layer and electrically connected to the second penetration electrode and the second contact plug.

11. The semiconductor device of claim 10, further comprising:
a third insulation layer on the first insulation layer; and
a fourth insulation layer on the second insulation layer,
wherein the first connection pattern portion is within the third insulation layer, and the second connection pattern portion is within the fourth insulation layer.

12. The semiconductor device of claim 11, further comprising:
a first pad portion electrically connected to the first connection pattern portion; and
a second pad portion electrically connected to the second connection pattern portion,
wherein the second penetration electrode is electrically connected to an external pad portion through one or more of the first pad portion and the second pad portion.

13. The semiconductor device of claim 12, wherein the second driving transistor is configured to receive a second signal from the second penetration electrode through the second contact plug and the second connection pattern portion, and
wherein the second contact plug extends into the second surface of the substrate.

14. The semiconductor device of claim 1, further comprising:
a third contact plug extending in the first insulation layer and electrically connected to the second driving transistor; and
a first connection pattern portion on the first insulation layer and electrically connected to the third contact plug,
wherein the second contact plug extends in the substrate, the second insulation layer, and the first insulation layer, and
wherein the second driving transistor is electrically connected to the second contact plug through the first connection pattern portion and the third contact plug.

15. The semiconductor device of claim 1, wherein the substrate comprises a cell array region, a core region, and a connection region,
wherein the first driving transistor and the second driving transistor are in the core region,
wherein the first penetration electrode and the second penetration electrode are in the connection region, and
wherein the semiconductor device further comprises a memory cell in the cell array region.

16. A semiconductor device, comprising:
a die;
a plurality of semiconductor chips electrically connected to the die and stacked along a first direction; and
a molding material that at least partially surrounds the plurality of semiconductor chips,
wherein at least one of the plurality of semiconductor chips comprises:
a substrate comprising a cell array region, a core region, and a connection region, the substrate having a first surface and a second surface opposite to each other;
a first driving transistor and a second driving transistor on the first surface of the substrate and in the core region;
a first insulation layer on the first surface of the substrate;
a second insulation layer on the second surface of the substrate;
a first penetration electrode and a second penetration electrode that are in the connection region and extend into the substrate, the first insulation layer, and the second insulation layer;
a first contact plug extending in the first insulation layer and electrically connected to the first driving transistor and the first penetration electrode; and
a second contact plug extending in the substrate and the second insulation layer and electrically connected to the second driving transistor and the second penetration electrode.

17. The semiconductor device of claim 16, further comprising:
a first connection pattern portion on the first insulation layer; and
a second connection pattern portion on the second insulation layer and electrically connected to the first penetration electrode,
wherein the first connection pattern portion is electrically connected between the first penetration electrode and the first contact plug.

18. The semiconductor device of claim 17, further comprising:
a third connection pattern portion on the first insulation layer and electrically connected to the second penetration electrode; and
a fourth connection pattern portion on the second insulation layer and electrically connected to the second penetration electrode and the second contact plug.

19. The semiconductor device of claim 18, further comprising:
a first pad portion electrically connected to the first connection pattern portion;
a second pad portion electrically connected to the second connection pattern portion;
a third pad portion electrically connected to the third connection pattern portion; and
a fourth pad portion electrically connected to the fourth connection pattern portion,
wherein the first penetration electrode is electrically connected to another one of the plurality of semiconductor chips through one or more of the first pad portion and the second pad portion, and
wherein the second penetration electrode is electrically connected to the another one of the plurality of semiconductor chips through one or more of the third pad portion and the fourth pad portion.

20. A semiconductor device, comprising:
a substrate that comprises a first surface and a second surface opposite to each other;
a first driving transistor and a second driving transistor on the first surface of the substrate;
a first insulation layer on the first surface of the substrate;
a second insulation layer on the second surface of the substrate;
a first contact plug extending in the first insulation layer and electrically connected to the first driving transistor; and
a second contact plug extending in the substrate and the second insulation layer and electrically connected to the second driving transistor,
wherein the first driving transistor is configured to receive a first signal through the first contact plug, and the second driving transistor is configured to receive a second signal through the second contact plug, and
wherein one of the first and second signals is a data signal, and another one of the first and second signals is a power signal.
